(19) United States
(12) Patent Application Publication
(10) Pub. No.: US 2025/0241077 A1
(43) Pub. Date: Jul. 24, 2025

(54) SEMICONDUCTOR DEVICE, ELECTRONIC DEVICE, AND METHOD FOR PRODUCING SEMICONDUCTOR DEVICE

(71) Applicant: SONY SEMICONDUCTOR SOLUTIONS CORPORATION, Kanagawa (JP)

(72) Inventor: Yui YUGA, Kanagawa (JP)

(73) Assignee: SONY SEMICONDUCTOR SOLUTIONS CORPORATION, Kanagawa (JP)

(21) Appl. No.: 18/703,667

(22) PCT Filed: Sep. 16, 2022
(86) PCT No.: PCT/JP2022/034678

§ 371 Date: Apr. 22, 2024

(30) Foreign Application Priority Data
Nov. 1, 2021 (JP) 2021-178710

(51) Int. Cl. H10F 39/00; H01L 25/18; H10F 39/12; H10F 77/30

(52) U.S. Cl. CPC H10F 39/805; H01L 25/18; H10F 39/024; H10F 39/809; H10F 77/306; H10F 39/12; H10F 39/811

(57) ABSTRACT

In order to regulate the characteristics of each of a plurality of individualized semiconductor elements, the present technique provides a semiconductor device including a first semiconductor element and a plurality of second semiconductor elements with a circuit configured to process a signal from the first semiconductor element, wherein the first semiconductor element and each of the plurality of second semiconductor elements are stacked and arranged; and a first film formed on at least one of the plurality of second semiconductor elements is different in configuration from a second film formed on another of the second semiconductor elements.

### TECHNICAL FIELD

The present technique relates to a semiconductor device, an electronic device, and a method for producing a semiconductor device.

### BACKGROUND ART

Conventionally, in the production of semiconductor devices, techniques to form films around semiconductor elements to protect the semiconductor elements or to enhance the characteristics of semiconductor elements have been used.

For example, PTL 1 describes “a semiconductor device having a first insulator, a transistor on the first insulator, a second insulator on the transistor, a first conductor embedded in an opening in the second insulator, a barrier layer on the first conductor, a third insulator on the second insulator and on the barrier layer, and a second conductor on the third insulator, characterized in that the first insulator, the third insulator, and the barrier layer have barrier properties to oxygen and hydrogen; the second insulator has an excess oxygen region; the transistor has an oxide semiconductor; and the barrier layer, the third insulator, and the second conductor have functions as capacitive elements”.

Furthermore, for example, PTL 2 describes “a method for preparing a semiconductor device, including the steps of: forming a first insulator; forming a second insulator on the first insulator; forming an island-shaped oxide on the second insulator; forming a stacked body of a third insulator and a conductor on the oxide; forming a film having a metal element on the oxide and the stacked body to selectively reduce the resistance of the oxide; forming a fourth insulator on the second insulator, the oxide, and the stacked body and then forming, on the fourth insulator, an opening to expose the second insulator; forming a fifth insulator on the second insulator and the fourth insulator; and introducing oxygen to the fifth insulator”.

### CITATION LIST

### Patent Literature

PTL 1: JP 2017-147443 A
PTL 2: WO 2019/048984

### SUMMARY

### Technical Problem

In the production of a semiconductor device, Chip on Wafer (CoW) techniques for mounting a plurality of individualized semiconductor elements on one wafer are used. Each of a plurality of semiconductor elements may have different characteristics. Therefore, there is a problem that when the film is uniformly formed for a plurality of semiconductor elements, the characteristics of each semiconductor element are difficult to regulate.

In light of the above state, the present technique has a main object to provide a semiconductor device for regulating the characteristics of each of a plurality of individualized semiconductor elements, an electronic device, and a method for producing a semiconductor device.

### Solution to Problem

The present technique provides a semiconductor device including a first semiconductor element and a plurality of second semiconductor elements with a circuit configured to process the signals from the first semiconductor element, wherein the first semiconductor element and each of the plurality of second semiconductor elements are stacked and arranged; and a first film formed on at least one of the plurality of second semiconductor elements is different in configuration from a second film formed on another of the second semiconductor elements.

The first film may be different in type from the second film.

The first film may be different in thickness from the second film.

The first film may be different in number from the second film.

The first film may have a stress-regulating function.

The first film may have a compressive stress-regulating function and may contain at least one selected from the group consisting of SiN, SiO2, TiN, TaN, and SiGe epitaxial layers.

The first film may have a tensile stress-regulating function and contain at least one selected from the group consisting of SiN and AlO.

The first film may contain a high melting point metal material.

The first film may contain at least one selected from the group consisting of SiON, AlN, Si, Ge, Mo, W, Ti, Ta, MoSi, WSi, and TiSi.

The first film may have an oxygen-regulating function.

The first film may have an oxygen-absorbing function and contain at least one selected from the group consisting of polysilicon, amorphous silicon, and SiGe.

The first film may have an oxygen supply function and contain at least one selected from the group consisting of aluminum, silicon, and hafnium and also may contain at least one selected from the group consisting of an oxide film, a nitride film, and an oxynitride film.

The first film may have an oxygen diffusion prevention function and contain at least one selected from the group consisting of boron, carbon, nitrogen, oxygen, fluorine, magnesium, aluminum, silicon, phosphorus, chlorine, argon, gallium, germanium, yttrium, zirconium, lanthanum, neodymium, hafnium, bismuth, niobium, tungsten, titanium, molybdenum, copper, ruthenium, nickel, or tantalum and also contain at least one selected from the group consisting of an oxide film, a nitride film, an oxynitride film, a metal, and an alloy.

The first film may have a hydrogen-regulating function.

The first film may have a hydrogen-absorbing function and contain at least one selected from the group consisting of Ti, Zr, Pd, V, Ta, Fe, Co, Ni, Cr, Pt, Cu, Ag, La, Th, Y, Nb, Hf, Sc, Lu, Ru, Rh, Ir, Os, and Mg.

The first film may have a hydrogen supply function and contain at least one selected from the group consisting of silicon nitride, silicon oxide, oxidized silicon carbide, HSQ, an organic film, TEOS, BPSG, BSG, PSG, FSG, carbon-containing silicon nitride, and amorphous silicon. The first film may have a hydrogen diffusion prevention function and contain at least one selected from the group consisting of silicon nitride, silicon oxynitride, low dielectric constant carbon-containing silicon oxide, silicon carbide, aluminum oxide, aluminum, tungsten, erbium oxide, a TiAl alloy, a nitride of a TiAl alloy, amorphous silicon, and SiC.

A plurality of the first semiconductor elements may be stacked and arranged.

The first semiconductor element, each of the plurality of second semiconductor elements, and the first semiconductor element may be stacked and arranged in this order.

The semiconductor device may further include a plurality of third semiconductor elements with a circuit configured to process a signal from the first semiconductor element, and each of the plurality of second semiconductor elements, the first semiconductor element, and each of the plurality of third semiconductor elements may be stacked and arranged in this order.

The first semiconductor element, each of the plurality of second semiconductor elements, and each of the third semiconductor elements may be stacked and arranged in this order.

Each of the plurality of second semiconductor elements may be different in orientation in plan view from each of the plurality of third semiconductor elements.

The semiconductor device may further include a support substrate.

The present technique also provides a method for producing a semiconductor device, including: joining a first semiconductor element and each of a plurality of second semiconductor elements with a circuit configured to process a signal from the first semiconductor element; forming first films on each of the plurality of second semiconductor elements; and patterning the first films so that the first films should remain on at least one of the plurality of second semiconductor elements.

According to the present technique, a semiconductor device for regulating the characteristics of each of a plurality of semiconductor elements, an electronic device, and a method for producing a semiconductor device can be provided. The effects described here are not necessarily limited and may be any of the effects described in the present disclosure.

### BRIEF DESCRIPTION OF DRAWINGS

FIG. 1 is a simplified cross-sectional view illustrating a comparative example of a semiconductor device 100 according to one embodiment of the present technique.

FIG. 2 is a simplified cross-sectional view illustrating a configuration example of a semiconductor device 100 according to one embodiment of the present technique.

FIG. 3 is a simplified cross-sectional view illustrating a configuration example of a semiconductor device 100 according to one embodiment of the present technique.

FIG. 4 is a simplified cross-sectional view illustrating a configuration example of a semiconductor device 100 according to one embodiment of the present technique.

FIG. 5 is a simplified cross-sectional view illustrating a configuration example of a semiconductor device 100 according to one embodiment of the present technique.

FIG. 6 is a simplified cross-sectional view illustrating a configuration example of a semiconductor device 100 according to one embodiment of the present technique.

FIG. 7 is a simplified cross-sectional view illustrating a configuration example of a semiconductor device 100 according to one embodiment of the present technique.

FIG. 8 is a simplified cross-sectional view illustrating a configuration example of a semiconductor device 100 according to one embodiment of the present technique.

FIG. 9 is a simplified cross-sectional view illustrating a configuration example of a semiconductor device 100 according to one embodiment of the present technique.

FIG. 10 is a simplified cross-sectional view illustrating a configuration example of a semiconductor device 100 according to one embodiment of the present technique.

FIG. 11 is a simplified cross-sectional view illustrating a configuration example of a semiconductor device 100 according to one embodiment of the present technique.

FIG. 12 is a simplified cross-sectional view illustrating a configuration example of a semiconductor device 100 according to one embodiment of the present technique.

FIG. 13 is a simplified cross-sectional view illustrating a configuration example of a semiconductor device 100 according to one embodiment of the present technique.

FIG. 14 is a simplified cross-sectional view illustrating a configuration example of a semiconductor device 100 according to one embodiment of the present technique.

FIG. 15 is a simplified cross-sectional view illustrating a configuration example of a semiconductor device 100 according to one embodiment of the present technique.

FIG. 16 is a simplified cross-sectional view illustrating a configuration example of a semiconductor device 100 according to one embodiment of the present technique.

FIG. 17 is a simplified cross-sectional view illustrating a configuration example of a semiconductor device 100 according to one embodiment of the present technique.

FIG. 18 is a simplified cross-sectional view illustrating a configuration example of a semiconductor device 100 according to one embodiment of the present technique.

FIG. 19 is a simplified cross-sectional view illustrating a configuration example of a semiconductor device 100 according to one embodiment of the present technique.

FIG. 20 is a simplified cross-sectional view illustrating a configuration example of a semiconductor device 100 according to one embodiment of the present technique.

FIG. 21 is a simplified cross-sectional view illustrating a configuration example of a semiconductor device 100 according to one embodiment of the present technique.

FIG. 22 is a simplified cross-sectional view illustrating a configuration example of a semiconductor device 100 according to one embodiment of the present technique.

FIG. 23 is a simplified cross-sectional view illustrating a configuration example of a semiconductor device 100 according to one embodiment of the present technique.

FIG. 24 is a simplified cross-sectional view illustrating a configuration example of a semiconductor device 100 according to one embodiment of the present technique.

FIG. 25 is a diagram illustrating a usage example of the semiconductor device according to one embodiment of the present technique.

FIG. 26 is a block diagram illustrating a configuration example of an image-capturing device as an electronic device to which the present technique is applied.

FIG. 27 is a diagram illustrating one example of a schematic configuration of an endoscopic surgery system to which the semiconductor device according to one embodiment of the present technique is applicable.

FIG. 28 is a block diagram illustrating one example of a functional configuration of a camera head 11102 and a CCU 11201.

FIG. 29 is a block diagram illustrating a schematic configuration example of a vehicle control system, which is one example of a moving body control system to which the present technique is applicable.

FIG. 30 is a diagram illustrating an example of the installation position of an image-capturing unit 12031.

FIG. 31 is a diagram illustrating an example of a production process of a semiconductor device 100 according to one embodiment of the present technique.

FIG. 32 is a diagram illustrating an example of a production process of a semiconductor device 100 according to one embodiment of the present technique.

FIG. 33 is a diagram illustrating an example of a production process of a semiconductor device 100 according to one embodiment of the present technique.

### DESCRIPTION OF EMBODIMENTS

The following is a description of preferable embodiments for implementing the present technique with reference to the drawings. The embodiments which will be described below show an example of representative embodiments of the present technique, and the scope of the present technique should not be limited on the basis of these embodiments. Furthermore, any of the following Examples and modifications thereof may be combined in the present technique.

In the description of the embodiments below, configurations may be described using terms with “substantially”, such as substantially parallel or substantially orthogonal. For example, the term “substantially parallel” means not only fully parallel but also practically parallel; that is, the term includes a state that deviates from a completely parallel state by, for example, a few percent. The same applies to other terms with “substantially”. Furthermore, the drawings are schematic diagrams and are not necessarily exact illustrations.

In the drawings, unless otherwise specified, “up” means the upper direction or the upper side in the drawing, “down” means the lower direction or the lower side in the drawing, “left” means the left direction or the left side in the drawing, and “right” means the right direction or the right side in the drawing. Also, the same reference signs will be given to the same or equivalent elements or members in the drawings, and redundant descriptions thereof will not be given.

The description will be given in the following order.
1. Overview
2. First Embodiment (Example 1 of Semiconductor Device)
(1) Configuration Example
(2) Stress-Regulating Function
(3) Oxygen-Regulating Function
(4) Hydrogen-Regulating Function
(5) Other Configuration Examples
3. Second Embodiment (Example 2 of Semiconductor Device)
4. Third Embodiment (Example 3 of Semiconductor Device)
5. Fourth Embodiment (Example 4 of Semiconductor Device)
6. Fifth Embodiment (Example 5 of Semiconductor Device)
7. Sixth Embodiment (Example 6 of Semiconductor Device)
8. Seventh Embodiment (Example of Electronic Device)
9. Example of Use of Semiconductor Device to Which Present Technique is Applied
10. Examples of Applications of Semiconductor Device to Which Present Technique is Applied
11. Eighth Embodiment of Present Technique (Example 1 of Method for Producing Semiconductor Device)
12. Ninth Embodiment of Present Technique (Example 2 of Method for Producing Semiconductor Device)
13. Tenth Embodiment of Present Technique (Example 3 of Method for Producing Semiconductor Device)

### 1. Overview

In the production of semiconductor devices, Wafer on Wafer (WoW) techniques, in which a plurality of wafers are stacked and bonded together, have been used. For example, in these WOW techniques, a wafer on which a plurality of semiconductor elements are formed, a wafer on which a plurality of memory circuits are formed, and a wafer on which a plurality of logic circuits are formed are stacked and arranged. This allows each of the semiconductor devices, memory circuits, and logic circuits to be electrically connected with fine pitches.

However, since the areas required for each of the semiconductor devices, memory circuits, and logic circuits are different, wasted spaces may occur on a wafer. In addition, if any one of the semiconductor devices, memory circuits, and logic circuits is defective, non-defective semiconductor devices, memory circuits, or logic circuits stacked on defective semiconductor devices, memory circuits, or logic circuits will also be discarded. As a result, a problem of production cost increase occurs.

In order to solve this problem, Chip on Wafer (CoW) techniques for mounting a plurality of semiconductor elements that have been individualized in advance on one wafer are used. These techniques save the production cost without forming waste on a wafer.

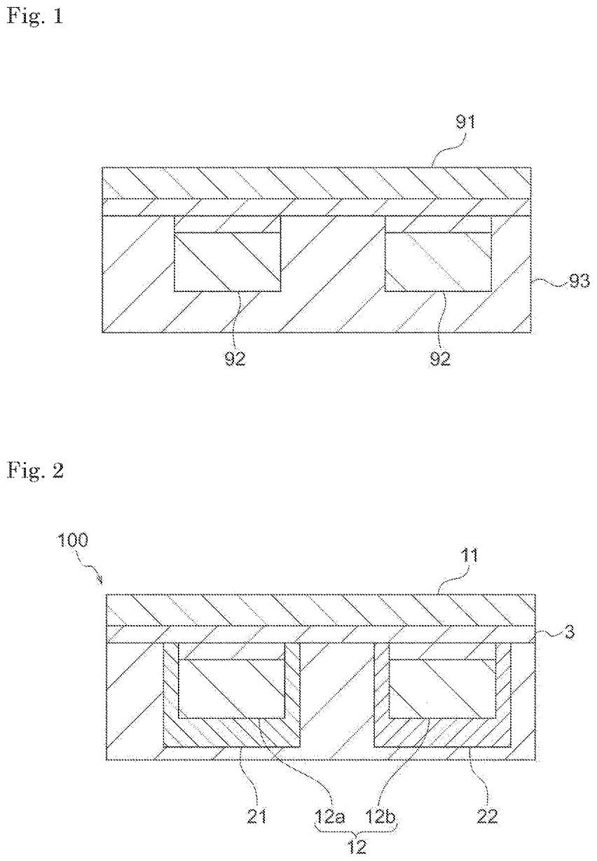

Normally, a film is uniformly formed around a plurality of these individualized semiconductor elements. This will be described with reference to FIG. 1. FIG. 1 is a simplified cross-sectional view illustrating a comparative example of a semiconductor device 100 according to one embodiment of the present technique. As illustrated in FIG. 1, in this comparative example, a first semiconductor element 91 and each of a plurality of second semiconductor elements 92 that are individualized in advance and have a circuit (illustration omitted) configured to process the signals from the first semiconductor element 92 are stacked and arranged. For example, a film 93, such as oxide film, is uniformly formed around each of the second semiconductor elements 92.

However, each second semiconductor element may have different characteristics. For example, a specific second semiconductor element may have compression inner stress or tensile inner stress. This may cause a problem of deformation of the second semiconductor elements. This problem may be a major issue in achieving miniaturization of semiconductor devices.

Therefore, the inventor has made intensive studies to solve this problem and has completed this technique.

### 2. First Embodiment (Example 1 of Semiconductor Device)

### (1) Configuration Example

A semiconductor device according to one embodiment of this technique is a semiconductor device provided with a first semiconductor element and a plurality of second semiconductor elements with a circuit configured to process the signals from the first semiconductor element, wherein the first semiconductor element and each of the plurality of second semiconductor elements are stacked and arranged; and a first film formed on at least one of the plurality of second semiconductor elements is different in configuration from a second film formed on another of the second semiconductor elements.

A configuration example of a semiconductor device according to one embodiment of the present technique will be described with reference to FIG. 2. FIG. 2 is a simplified cross-sectional view illustrating a configuration example of a semiconductor device 100 according to one embodiment of the present technique. As illustrated in FIG. 2, a semiconductor device 100 according to one embodiment of the present technique is provided with a first semiconductor element 11 and a plurality of second semiconductor elements 12 with a circuit (illustration omitted) configured to process the signals from the first semiconductor element 11. Each of the plurality of second semiconductor elements 12 is individualized.

The first semiconductor element 11 and each of the plurality of second semiconductor elements 12 are stacked and arranged. More specifically, the first semiconductor element 11, an oxide film bonding layer 3, and each of the plurality of second semiconductor elements 12 are stacked and arranged. The first semiconductor element 11 and each of the plurality of second semiconductor elements 12 are electrically connected by, for example, Cu—Cu bonding or the like.

For example, the first semiconductor element 11 and each of the second semiconductor elements 12 may be provided with a signal processing circuit, such as a logic circuit and a memory circuit, a communication device, a sensor, and the like.

Here, a first film 21 formed on at least one of the plurality of second semiconductor elements 12 is different in configuration from a second film 22 formed on another of the second semiconductor elements 12. These will be described below.

### (2) Stress-Regulating Function

The first film 21 may be different in type from the second film 22. For example, the first film 21 may have a stress-regulating function. Each of a plurality of individualized semiconductor elements may produce compressive stress or tensile stress. Therefore, for example, the first film 21 may have a compressive stress-regulating function, and the second film 22 may have a tensile stress-regulating function. Alternatively, the first film 21 may have a tensile stress-regulating function, and the second film 22 may have a compressive stress-regulating function.

In order for the first film 21 to have a compressive stress-regulating function, it is preferred that the first film 21 contains at least one selected from the group consisting of SiN, SiO2, TiN, TaN, and SiGe epitaxial layers. This reduces the warpage of a chip due to the stress produced in the second semiconductor element 12, on which the first film 21 is formed.

For the first film 21 to have a tensile stress-regulating function, it is preferred that the first film 21 contains at least one selected from the group consisting of SiN and AlO. This reduces the warpage of a chip due to the stress produced in the second semiconductor element 12, on which the first film 21 is formed.

Otherwise, for the first film 21 to have a stress-regulating function, it is preferable that the first film 21 contain a high melting point metal material. Examples of high melting point metal materials include Mo, W, Ti, Ta, MoSi, WSi, TiSi, and the like. For example, the first film 21 may contain a semiconductor such as SiON, AlN, Si, and Ge, a high melting point metal material such as Mo, W, Ti, and Ta, or a compound of a high melting point material and Si, such as MoSi, WSi, and TiSi. That is, the first film 21 may contain at least one selected from the group consisting of SiON, AlN, Si, Ge, Mo, W, Ti, Ta, MoSi, WSi, and TiSi

This relives the stress produced in the second semiconductor element 12, on which the first film 21 is formed.

### (3) Oxygen-Regulating Function

Alternatively, for example, the reliability of the semiconductor element can be increased by increasing or reducing gas, such as hydrogen, oxygen, or nitrogen, to a specific semiconductor element.

Then, for example, the first film 21 may have an oxygen-regulating function. For example, the first film 21 may have an oxygen-absorbing function, and the second film 22 may have an oxygen supply function. Alternatively, the first film 21 may have an oxygen-absorbing function, and the second film 22 may have an oxygen supply function. Alternatively, the first film 21 may have an oxygen diffusion prevention function, and the second film 22 may have an oxygen-absorbing function.

For the first film 21 to have an oxygen-absorbing function, it is preferred that the first film 21 contains at least one selected from the group consisting of polysilicon, amorphous silicon, and SiGe. This allows oxygen in the second semiconductor element 12, on which the first film 21 is formed, to be absorbed by the first film 21 and reduces oxygen in the second semiconductor element 12.

For the first film 21 to have an oxygen supply function, it is preferred that the first film 21 contains at least one selected from the group consisting of aluminum, silicon, and hafnium and also contains at least one selected from the group consisting of an oxide film, a nitride film, and an oxynitride film. This allows oxygen to be supplied to the second semiconductor element 12, on which the first film 21 is formed, and increases oxygen in the second semiconductor element 12.

For the first film 21 to have an oxygen diffusion prevention function, it is preferred that the first film 21 contains at least one selected from the group consisting of boron, carbon, nitrogen, oxygen, fluorine, magnesium, aluminum, silicon, phosphorus, chlorine, argon, gallium, germanium, yttrium, zirconium, lanthanum, neodymium, hafnium, bismuth, niobium, tungsten, titanium, molybdenum, copper, ruthenium, nickel, or tantalum and also contain at least one selected from the group consisting of an oxide film, a nitride film, an oxynitride film, a metal, and an alloy. This prevents the diffusion of oxygen formed in the second semiconductor element 12, on which the first film 21 is formed.

### (4) Hydrogen-Regulating Function

The first film 21 may have a hydrogen-regulating function. For example, the first film 21 may have a hydrogen-absorbing function, and the second film 22 may have a hydrogen supply function. Alternatively, the first film 21 may have a hydrogen-absorbing function, and the second film 22 may have a hydrogen supply function. Alternatively, the first film 21 may have a hydrogen diffusion prevention function, and the second film 22 may have a hydrogen-absorbing function.

For the first film 21 to have a hydrogen-absorbing function, it is preferred that the first film 21 contains at least one selected from the group consisting of Ti, Zr, Pd, V, Ta, Fe, Co, Ni, Cr, Pt, Cu, Ag, La, Th, Y, Nb, Hf, Sc, Lu, Ru, Rh, Ir, Os, and Mg. This allows hydrogen in the second semiconductor element 12, on which the first film 21 is formed, to be absorbed by the first film 21 and reduces hydrogen in the second semiconductor element 12.

For the first film 21 to have a hydrogen supply function, it is preferred that the first film 21 contains at least one selected from the group consisting of silicon nitride, silicon oxide, oxidized silicon carbide, HSQ, an organic film, TEOS, BPSG, BSG, PSG, FSG, carbon-containing silicon nitride, and amorphous silicon. This allows hydrogen to be supplied to the second semiconductor element 12, on which the first film 21 is formed, and increases hydrogen in the second semiconductor element 12.

For the first film 21 to have a hydrogen diffusion prevention function, it is preferred that the first film 21 contains at least one selected from the group consisting of silicon nitride, silicon oxynitride, low dielectric constant carbon-containing silicon oxide, silicon carbide, aluminum oxide, aluminum, tungsten, erbium oxide, TiAl alloy, a nitride of TiAl alloy, amorphous silicon, and SiC. This prevents the diffusion of hydrogen formed on the second semiconductor element 12, in which the first film 21 is formed.

### (5) Other Configuration Examples

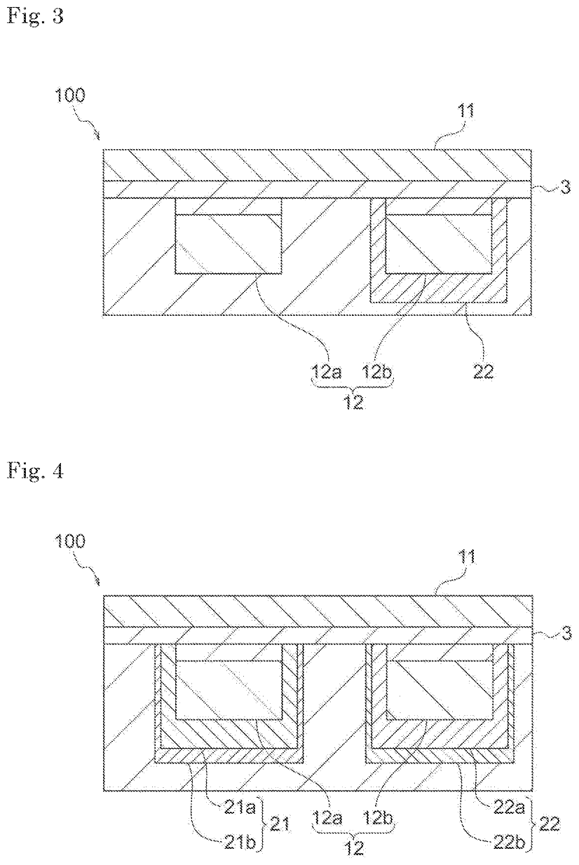

A configuration example of a semiconductor device according to one embodiment of the present technique will be described with reference to FIG. 3. FIG. 3 is a simplified cross-sectional view illustrating a configuration example of a semiconductor device 100 according to one embodiment of the present technique. As illustrated in FIG. 3, the second film 22 may be formed only on the second semiconductor element 12b out of the plurality of second semiconductor elements 12.

This second film 22 may have a stress-regulating function, an oxygen-regulating function, or a hydrogen-regulating function as with the first film 21 described above.

A configuration example of a semiconductor device according to one embodiment of the present technique will be described with reference to FIG. 4. FIG. 4 is a simplified cross-sectional view illustrating a configuration example of a semiconductor device 100 according to one embodiment of the present technique. As illustrated in FIG. 4, each of the first film 21 and the second film 22 may be formed by a plurality of films. The first film 21 is formed from a film 21a and a film 21b. The second film 22 is formed from a film 22a and a film 22b. Each of the film 21a and the film 21b may be of different types. For example, the film 21a may have a stress-regulating function, and the film 21b may have a hydrogen-regulating function.

The above description of the semiconductor device according to the first embodiment of the present technique can be applied to other embodiments of the present technique as long as there is no particular technical contradiction.

### 3. Second Embodiment (Example 2 of Semiconductor Device)

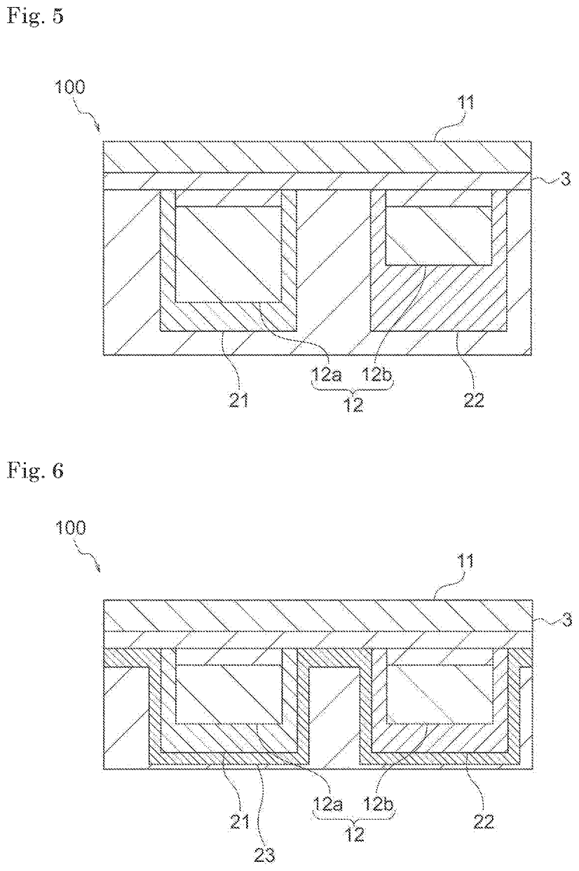

The films formed on each of the plurality of second semiconductor elements may have different thicknesses. This will be described with reference to FIG. 5. FIG. 5 is a simplified cross-sectional view illustrating a configuration example of a semiconductor device 100 according to one embodiment of the present technique. As illustrated in FIG. 5, the thickness of the first film 21 is different from that of the second film 22. This allows the total thicknesses of a combination of the second semiconductor element 12a or 12b and the films to be substantially equivalent, even if the thicknesses of the second semiconductor element 12a and the second semiconductor element 12b are different. As a result, chemical mechanical polishing (CMP) for polishing and flattening the surface of a wafer becomes easy to perform.

The above description of the semiconductor device according to the second embodiment of the present technique can be applied to other embodiments of the present technique as long as there is no particular technical contradiction.

### 4. Third Embodiment (Example 3 of Semiconductor Device)

The same type of films may be uniformly formed on each of a plurality of second semiconductor elements. This will be described with reference to FIG. 6. FIG. 6 is a simplified cross-sectional view illustrating a configuration example of a semiconductor device 100 according to one embodiment of the present technique. As illustrated in FIG. 6, a first film 21 is formed on a second semiconductor element 12a. A second film 22 is formed on a second semiconductor element 12b. Then, a third film 23 is uniformly formed on each of the second semiconductor element 12a and the second semiconductor element 12b. This third film 23 may have at least one selected from the group consisting of a stress-regulating function, an oxygen-regulating function, and a hydrogen-regulating function as with the first film 21 and the second film 22. In particular, this third film 23 may have an oxygen-regulating function or a hydrogen-regulating function.

In this configuration example, the first film 21 with a hydrogen-absorbing function may be formed on the second semiconductor element 12a, in which less hydrogen is preferred. The second film 22 with a hydrogen supply function may be formed on the second semiconductor element 12b, in which more hydrogen is preferred. Then, a third film 23 with a hydrogen diffusion prevention function may be uniformly formed on each of the second semiconductor element 12a and the second semiconductor element 12b. This allows the hydrogen amount for each of the second semiconductor elements to be adjusted to be optimal.

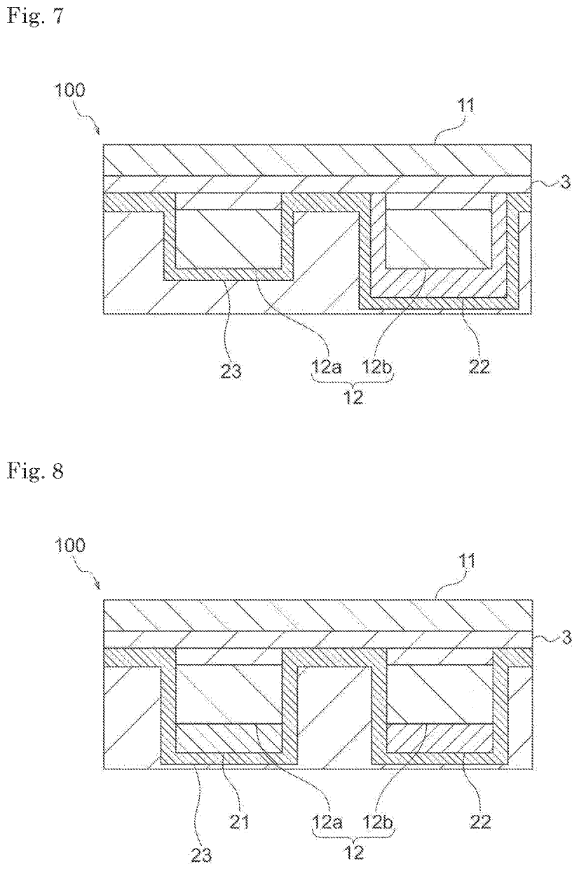

The number of films formed on each of the plurality of second semiconductor elements may be different. This will be described with reference to FIG. 7. FIG. 7 is a simplified cross-sectional view illustrating a configuration example of a semiconductor device 100 according to one embodiment of the present technique. As illustrated in FIG. 7, in this configuration example, a first film 23 is formed on a second semiconductor element 12a, and a second film composed of a film 22 and a film 23 is formed on a second semiconductor element 12b. The number of the first film 23 is different from the number of the second film (the films 22 and 23).

In this configuration example, the film 22 included in the second film may have an oxygen supply function. The film 23 uniformly formed on each of the second semiconductor element 12 and the second semiconductor element 12 may have an oxygen diffusion prevention function. This allows more oxygen to be supplied to the second semiconductor element 12b. As a result, lower resistance can be achieved for a transistor or the like in the second semiconductor element 12b.

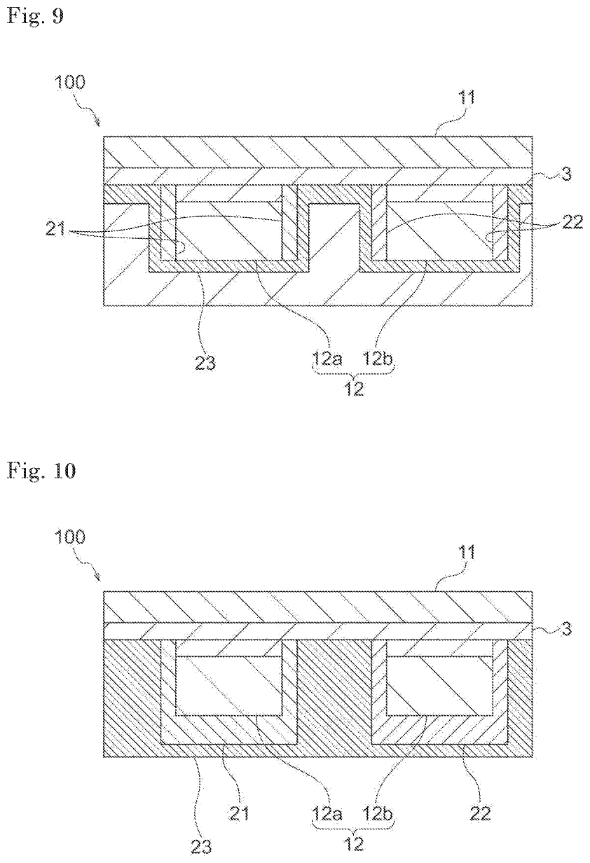

The same type of film is uniformly formed on each of the plurality of second semiconductor elements, and when this film has an oxygen diffusion prevention function or a hydrogen diffusion prevention function, a film arranged closer to the second semiconductor element than this film may be formed on a part of the second semiconductor element. This will be described with reference to FIGS. 8 and 9. FIGS. 8 and 9 are simplified cross-sectional views illustrating configuration examples of semiconductor devices 100 according to one embodiment of the present technique.

As illustrated in FIG. 8, a first film 21 is formed on a mounting surface of a second semiconductor element 12a, and a second film 22 is formed on a mounting surface of a second semiconductor element 12b. A third film 23 is uniformly formed on each of the second semiconductor element 12a and the second semiconductor element 12b.

Furthermore, as illustrated in FIG. 9, a first film 21 is formed on the side surface of a second semiconductor element 12a, and a second film 22 is formed on the side surface of a second semiconductor element 12b. A third film 23 is uniformly formed on each of the second semiconductor element 12a and the second semiconductor element 12b.

Although not illustrated, for example, the first film 21 may be formed on a mounting surface of the second semiconductor element 12, and the second film 22 may be formed on the side surface of the second semiconductor element 12.

Such a configuration can intensively enhance the properties of any constitutional element of the second semiconductor element 12. For example, lower resistance of a transistor can be more efficiently achieved by forming a film with an oxygen supply function near the position where the transistor of the second semiconductor element 12 is arranged.

Another configuration example according to one embodiment of the present technique will be described with reference to FIG. 10. FIG. 10 is a simplified cross-sectional view illustrating a configuration example of a semiconductor device 100 according to one embodiment of the present technique. As illustrated in FIG. 10, a first film 21 is formed on a second semiconductor element 12. A second film 22 is formed on a second semiconductor element 12. Then, a third film 23 is uniformly formed on each of the second semiconductor element 12 and the second semiconductor element 12. This third film 23 is formed to be thicker than other configuration examples. This can enhance the diffusion prevention effect more greatly, for example, when this third film 23 has an oxygen diffusion prevention function or a hydrogen diffusion prevention function.

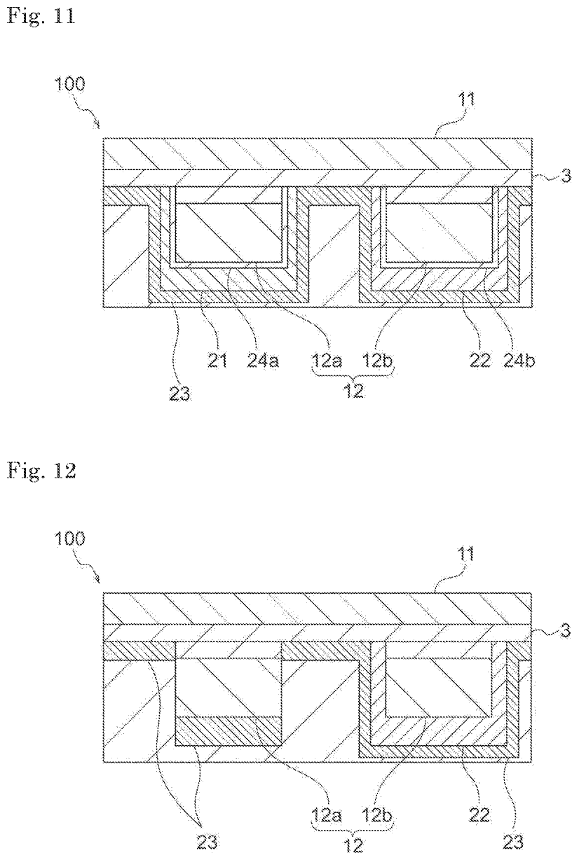

Another configuration example according to one embodiment of the present technique will be described with reference to FIG. 11. FIG. 11 is a simplified cross-sectional view illustrating a configuration example of a semiconductor device 100 according to one embodiment of the present technique.

As illustrated in FIG. 11, a thin fourth film 24a is formed on a second semiconductor element 12a. A first film 21 is formed outside the fourth film 24a. Similarly, a thin fourth film 24b is formed on a second semiconductor element 12b. The second film 22 is formed outside the fourth film 24b. Then, a third film 23 is uniformly formed on the outside of each of the first film 21 and the second film 22.

That is, the second semiconductor element 12a, the fourth film 24a, the first film 21, and the third film 23 are stacked and formed in this order. Furthermore, the second semiconductor element 12b, the fourth film 24b, the second film 22, and the third film 23 are stacked and formed in this order.

For example, when a fourth film 24 is an insulating film, each of the first film 21, the second film 22, and the third film 23 may be a highly thermally conductive film. This allows the heat generated in the second semiconductor element 12 to be dissipated outside the semiconductor device 100 via the first film 21, the second film 22, and the third film 23.

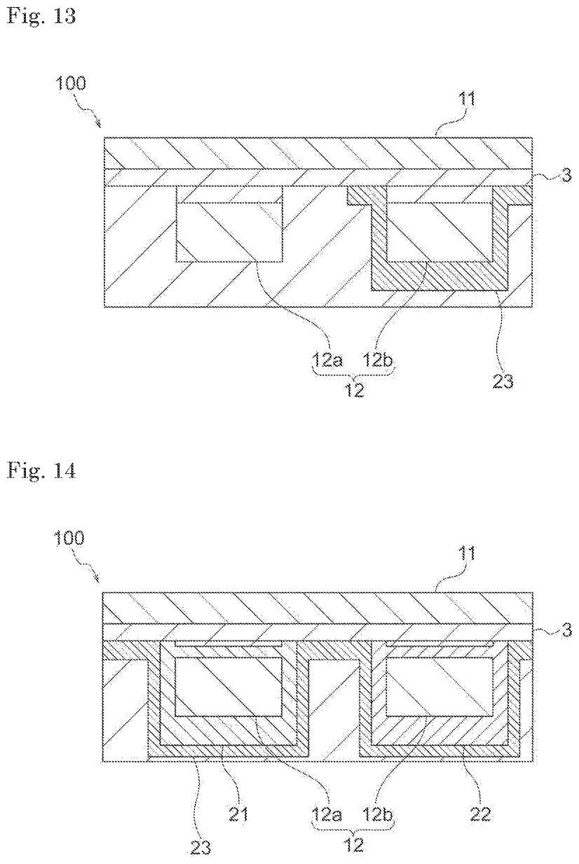

Another configuration example according to another configuration example of one embodiment of the present technique will be described with reference to FIGS. 12 and 13. FIGS. 12 and 13 are simplified cross-sectional views illustrating configuration examples of semiconductor devices 100 according to one embodiment of the present technique. As illustrated in FIG. 12, third films 23 are formed on each of a second semiconductor element 12a and a second semiconductor element 12b. Then, a part of the third film 23 formed on the second semiconductor element 12a is opened. Furthermore, as illustrated in FIG. 13, a third film 23 may not be formed on a second semiconductor element 12a, and a third film 23 may be formed on a second semiconductor element 12b.

Another configuration example according to one embodiment of the present technique will be described with reference to FIG. 14. FIG. 14 is a simplified cross-sectional view illustrating a configuration example of a semiconductor device 100 according to one embodiment of the present technique. As illustrated in FIG. 14, a first film 21 is formed on the entire surface of a second semiconductor element 12a, and a second film 22 is formed on the entire surface of a second semiconductor element 12b. Then, a third film 23 is uniformly formed on each of the first film 21 and a second film 22. Although not illustrated, the third film 23 may be formed on the entire surface of each of a second semiconductor element 12 and a second semiconductor element 12.

The above description of the semiconductor device according to the third embodiment of the present technique can be applied to other embodiments of the present technique as long as there is no particular technical contradiction.

### 5. Fourth Embodiment (Example 4 of Semiconductor Device)

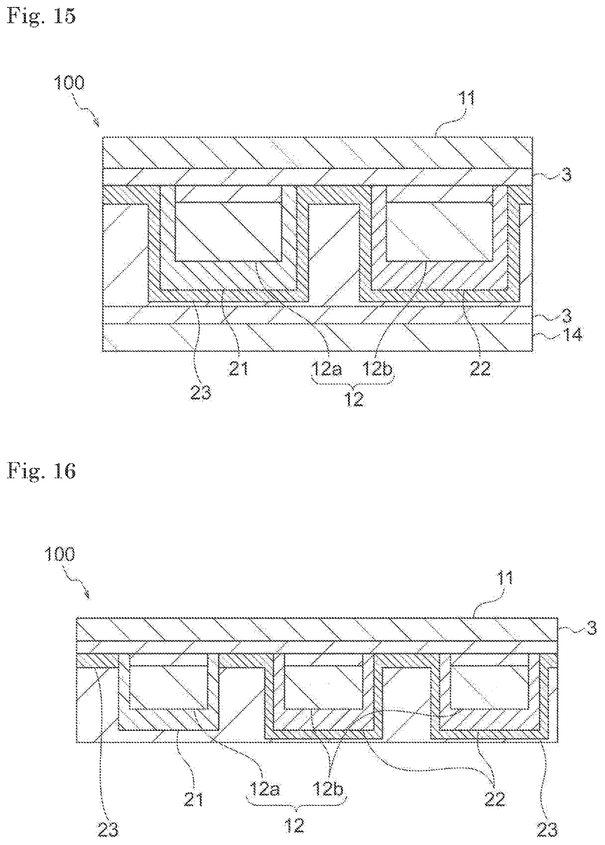

The semiconductor device according to one embodiment of the present technique may have a support substrate. This will be described with reference to FIG. 15. FIG. 15 is a simplified cross-sectional view illustrating a configuration example of a semiconductor device 100 according to one embodiment of the present technique. As illustrated in FIG. 15, a semiconductor device according to one embodiment of the present technique further includes a support substrate 14 containing, for example, silicon or the like. This support substrate 14 may be formed on the side opposite to the side where a first semiconductor element 11 is arranged.

For example, when a film formed on a second semiconductor element 12 is thin, there may be a problem that a semiconductor device may warp. This problem can be solved by including the support substrate 14.

The above description of the semiconductor device according to the fourth embodiment of the present technique can be applied to other embodiments of the present technique as long as there is no particular technical contradiction.

### 6. Fifth Embodiment (Example 5 of Semiconductor Device)

When a semiconductor device is provided with three or more second semiconductor elements 12, the configuration of films formed on two or more of the second semiconductor elements 12 may be the same. This will be described with reference to FIG. 16. FIG. 16 is a simplified cross-sectional view illustrating a configuration example of a semiconductor device 100 according to one embodiment of the present technique. As illustrated in FIG. 16, the semiconductor device 100 is provided with three second semiconductor elements 12. A first film 21 is formed on the second semiconductor element 12a, and a second film 22 is formed on two second semiconductor elements 12b.

The above description of the semiconductor device according to the fifth embodiment of the present technique can be applied to other embodiments of the present technique as long as there is no particular technical contradiction.

### 7. Sixth Embodiment (Example 6 of Semiconductor Device)

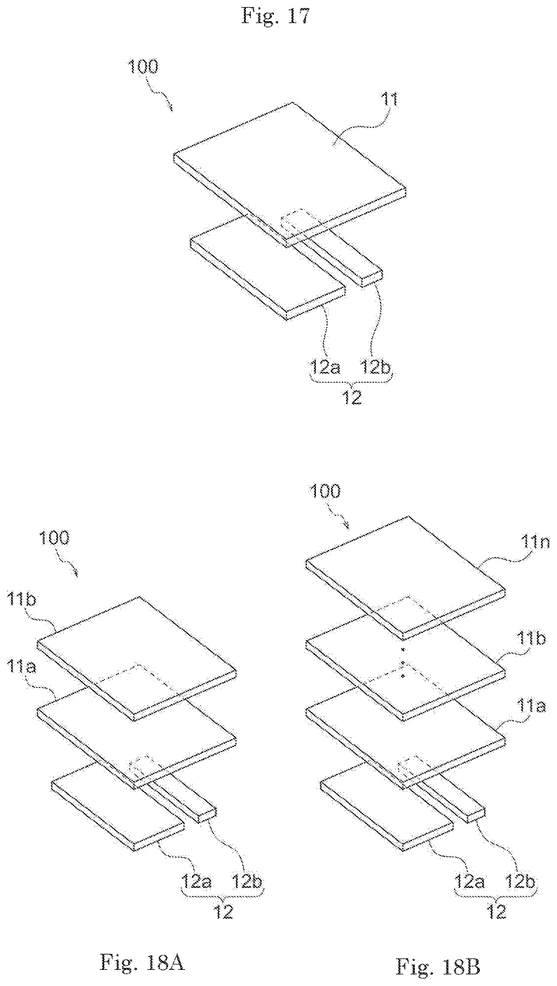

The arrangement and configurations of a first semiconductor element and a second semiconductor element will be described with reference to FIGS. 17 to 24. FIGS. 17 to 24 are cross-sectional views illustrating configuration examples of semiconductor devices 100 according to one embodiment of the present technique. In these configuration examples, individual films may be formed on each of a plurality of second semiconductor elements 12.

As illustrated in FIG. 17, a semiconductor device 100 according to one embodiment of the present technique is provided with a first semiconductor element 11 and a plurality of second semiconductor elements 12 with a circuit (illustration omitted) configured to process the signals from the first semiconductor element 11. Each of the plurality of second semiconductor elements 12 is individualized. The first semiconductor element 11 and each of the plurality of second semiconductor elements 12 are stacked and arranged.

As another configuration example, a plurality of the first semiconductor elements may be stacked and arranged. This will be described with reference to FIG. 18. As illustrated in FIG. 18A, a first semiconductor element 11a and a first semiconductor element 11b are stacked and arranged. Each of an individualized second semiconductor element 12 and an individualized second semiconductor element 12 and a first semiconductor element 11 are stacked and arranged.

Furthermore, as illustrated in FIG. 18B, three or more first semiconductor elements 11 may be stacked and arranged. In this configuration example, a first semiconductor element 11a, a first semiconductor element 11b, and a first semiconductor element 11n are stacked and arranged. One or more first semiconductor elements may be arranged between the first semiconductor element 11b and the first semiconductor element 11n.

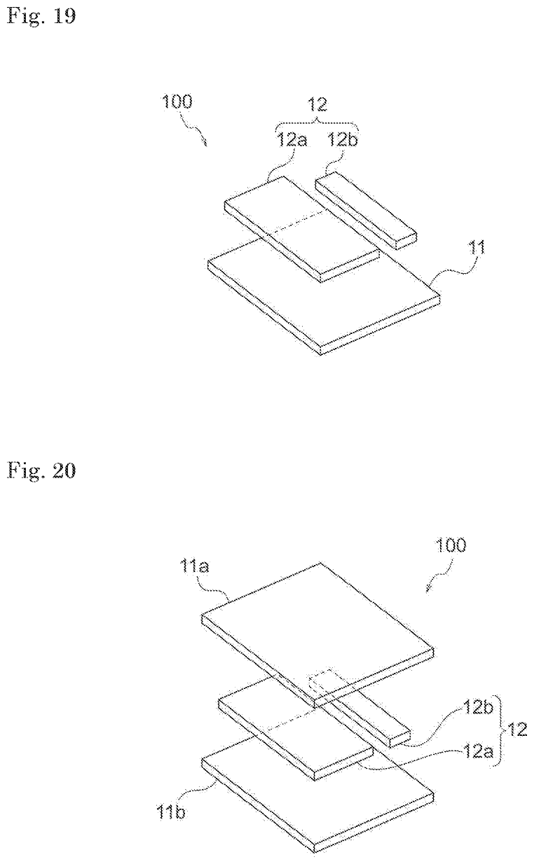

As another configuration example, each of a plurality of second semiconductor elements may be arranged on the upper side of the first semiconductor element. This will be described with reference to FIG. 19. As illustrated in FIG. 19, each of a plurality of second semiconductor elements 12 is stacked on the upper side of the first semiconductor element 11.

As another configuration example, a first semiconductor element, each of a plurality of second semiconductor elements, and a first semiconductor element may be stacked and arranged in this order. This will be described with reference to FIG. 20. As illustrated in FIG. 20, a first semiconductor element 11a, each of a plurality of second semiconductor elements 12, and a first semiconductor element 11b are stacked and arranged in this order.

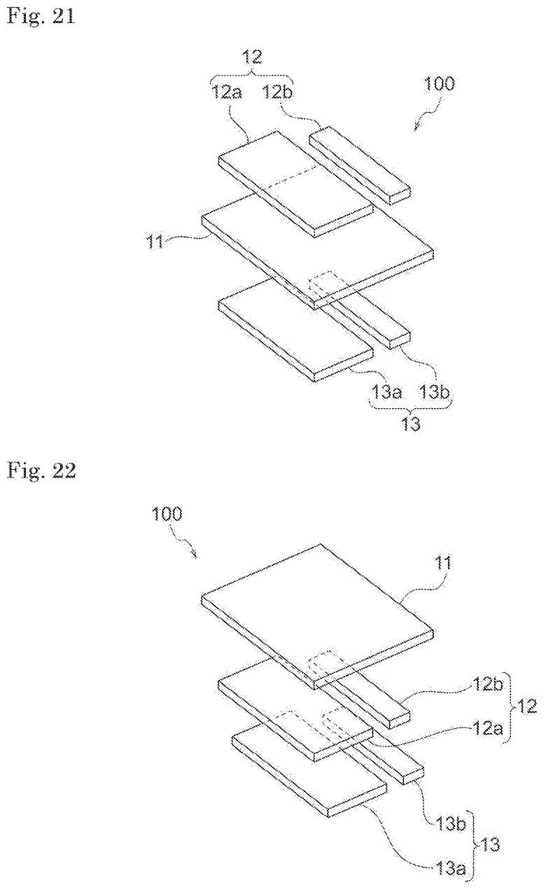

As another configuration example, a plurality of third semiconductor elements with a circuit configured to process the signals from the first semiconductor element may further be provided, and each of a plurality of second semiconductor elements, a first semiconductor element, and each of a plurality of third semiconductor elements may be stacked and arranged in this order. This will be described with reference to FIG. 21. As illustrated in FIG. 21, a semiconductor device 100 further includes a plurality of third semiconductor elements 13 with a circuit configured to process the signals from the first semiconductor element 11. Each of a plurality of second semiconductor elements 12, a first semiconductor element 11, and each of a plurality of third semiconductor elements 13 are stacked and arranged in this order.

As another configuration example, a first semiconductor element, each of a plurality of second semiconductor elements, and each of a plurality of third semiconductor elements may be stacked and arranged in this order. This will be described with reference to FIG. 22. As illustrated in FIG. 22, a first semiconductor element 11, each of a plurality of second semiconductor elements 12, and each of a plurality of third semiconductor elements 13 are stacked and arranged in this order.

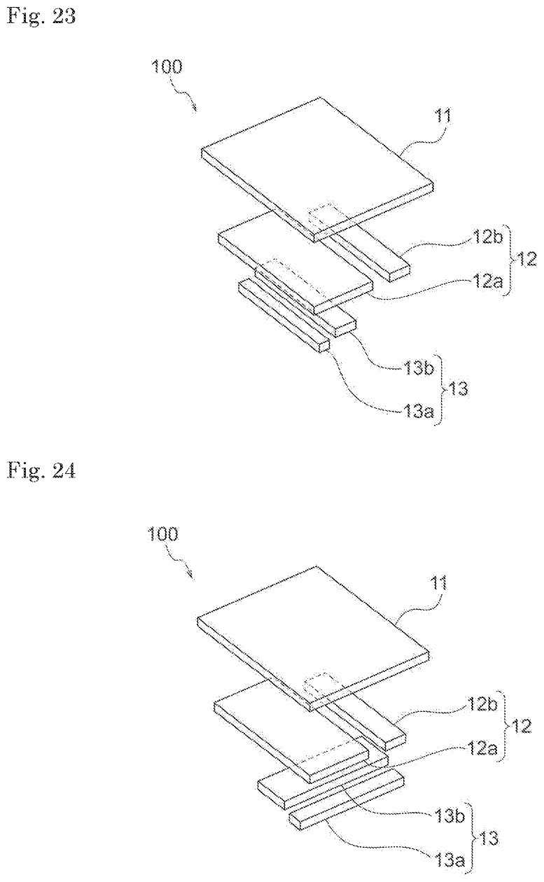

As another configuration example, each of the plurality of second semiconductor elements may be different in orientation in plan view from each of the plurality of third semiconductor elements. This will be described with reference to FIGS. 23 and 24.

In FIG. 23, a first semiconductor element 11, a second semiconductor element 12a, and each of a plurality of third semiconductor elements 13 are stacked and arranged in this order. Each of a plurality of second semiconductor elements 12 is different in orientation in plan view from each of the plurality of third semiconductor elements 13. Meanwhile, in FIG. 24, each of a plurality of second semiconductor elements 12 is different in orientation in plan view from each of a plurality of third semiconductor elements 13.

The above description of the semiconductor device according to the sixth embodiment of the present technique can be applied to other embodiments of the present technique as long as there is no particular technical contradiction.

### 8. Seventh Embodiment (Example of Electronic Device)

An electronic device according to one embodiment of the present technique is an electronic device provided with a semiconductor device of any one embodiment out of the first to sixth embodiments of the present technique. The following is a detailed description of an electronic device according to a seventh embodiment of the present technique.

### 9. Example of Use of Semiconductor Device to which Present Technique is Applied

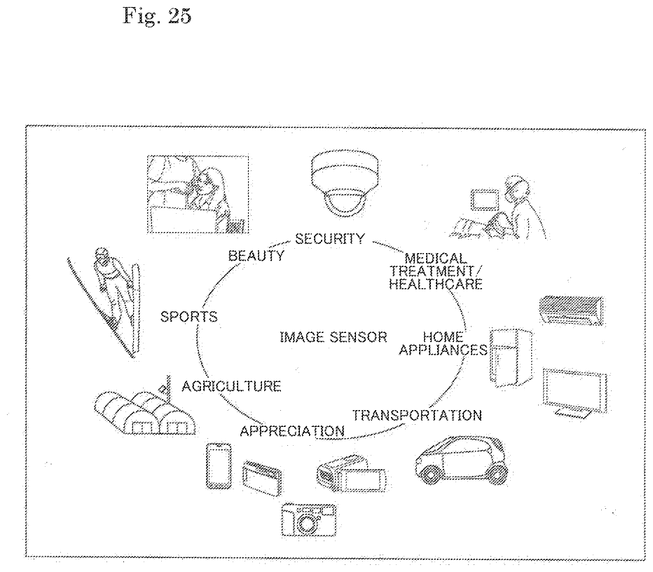

FIG. 25 is a diagram illustrating a usage example of a semiconductor device according to one embodiment of the present technique as a solid-state imaging device (image sensor).

For example, the semiconductor device according to one embodiment of the present technique can be used in various cases for sensing light, such as visible light, infrared light, ultraviolet light, and X-rays, as described below. That is, as illustrated in FIG. 25, a semiconductor device of any one embodiment out of the first to sixth embodiments can be used in a device (for example, an electronic device of the seventh embodiment described above) used in, for example, the field of appreciation for capturing images to be used for appreciation, the field of transportation, the field of home appliances, the field of medical treatment/healthcare, the field of security, the field of beauty, the field of sports, the field of agriculture, and the like.

Specifically, in the field of appreciation, a semiconductor device of any one embodiment of the first to sixth embodiments can be used in devices for capturing images provided for appreciation, such as a digital camera, a smartphone, and a mobile phone with a camera function.

In the field of transportation, a semiconductor device of any one embodiment of the first to sixth embodiments can be used in devices provided for transportation, such as an in-vehicle sensor that captures images of the front, rear, surroundings, inside, and the like of a vehicle, a monitoring camera that monitors traveling vehicles and roads, and a distance measuring sensor that measures a distance between vehicles, and the like for safe driving such as automatic stop, recognition of a driver's conditions, and the like.

In the field of home appliances, a semiconductor device of any one embodiment of the first to sixth embodiments can be used in devices provided for home appliances, such as a television receiver, a refrigerator, and an air conditioner, for example, in order to capture the images of a user's gesture and operate devices in response to the gesture.

In the field of medical treatment and health care, the semiconductor device of any one embodiment of the first to sixth embodiments can be used in devices provided for medical treatment and health care, such as an endoscope and a device that performs angiography by receiving infrared light.

In the field of security, the semiconductor device of any one embodiment of the first to sixth embodiments can be used in devices provided for security, such as a surveillance camera for crime prevention and a camera for person authentication.

In the field of beauty, the semiconductor device of any one embodiment of the first to sixth embodiments can be used in devices provided for beauty, such as a skin measuring instrument that captures the images of the skin and a microscope that captures the images of the scalp.

In the field of sports, the semiconductor device of any one embodiment of the first to sixth embodiments can be used in devices provided for sports, such as an action camera and a wearable camera for sports applications.

In the field of agriculture, the semiconductor device of any one embodiment of the first to sixth embodiments can be used in devices provided for agriculture, such as a camera that monitors the conditions of fields and crops.

The semiconductor device of any one embodiment of the first to sixth embodiments can be applied to various electronic devices, such as an image-capturing device, such as a digital still camera and a digital video camera, a cellular phone having an image-capturing function, or any other device with an image-capturing function.

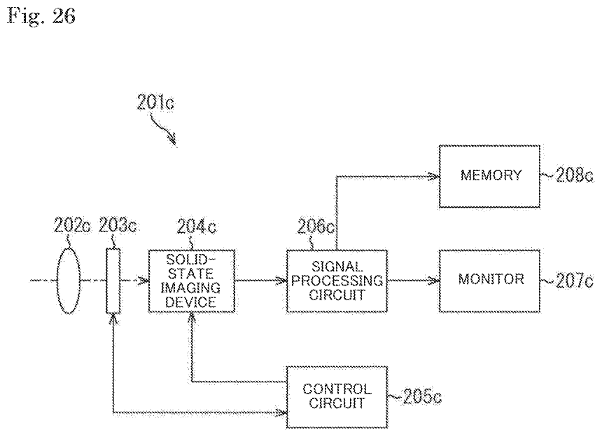

FIG. 26 is a block diagram illustrating a configuration example of an image-capturing device as an electronic device to which the present technique is applied.

The image-capturing device 201c illustrated in FIG. 26 is configured to include an optical system 202c, a shutter device 203c, a solid-state imaging device 204c, a drive circuit (control circuit) 205c, a signal processing circuit 206c, a monitor 207c, and a memory 208c and can capture still-images and moving images.

The optical system 202c is configured to include one or a plurality of lenses and directs light from an object (incident light) to the solid-state imaging device 204c and forms an image on the light-receiving surface of the solid-state imaging device 204c.

The shutter device 203c is arranged between the optical system 202c and the solid-state imaging device 204c and controls a light emission period and a light shielding period for the solid-state imaging device 204c according to the control by the drive circuit (control circuit) 205c.

The solid-state imaging device 204c accumulates signal charges for a certain period of time according to the light focused on the light-receiving surface to form images via the optical system 202c and the shutter device 203c. The signal charges accumulated in the solid-state imaging device 204c are transferred according to the drive signals (timing signals) supplied from the drive circuit (control circuit) 205c.

The drive circuit (control circuit) 205c outputs a drive signal that controls the transfer operation of the solid-state imaging device 204c and the shutter operation of the shutter device 203c and drives the solid-state imaging device 204c and the shutter device 203c.

The signal processing circuit 206c performs various signal processes on the signal charges output from the solid-state imaging device 204c. An image (image data) obtained by the signal processing performed by the signal processing circuit 206c is supplied to the monitor 207c and displayed, or supplied to the memory 208c and stored (recorded).

### 10. Examples of Applications of Semiconductor Device to which Present Technique is Applied

The following is a description of an example of an application of a semiconductor device (solid image-capturing device) according to one embodiment of the present technique. The semiconductor device according to one embodiment of the present technique can be applied to electronic devices in various fields. As one example, an endoscopic surgical system (Application Example 1) and a mobile unit (Application Example 2) are described here. It should be noted that the image-capturing device described in the section of the [9. Example of Use of Semiconductor Device to Which Present Technique is Applied] is also one of the examples of applications of a semiconductor device (solid image-capturing device) according to one embodiment of the present technique.

### Application Example 1

### Application Example to Endoscopic Surgery System

The semiconductor device according to one embodiment of the present technique can be applied to various products. For example, the semiconductor device according to one embodiment of the present technique may be applied to an endoscopic surgery system.

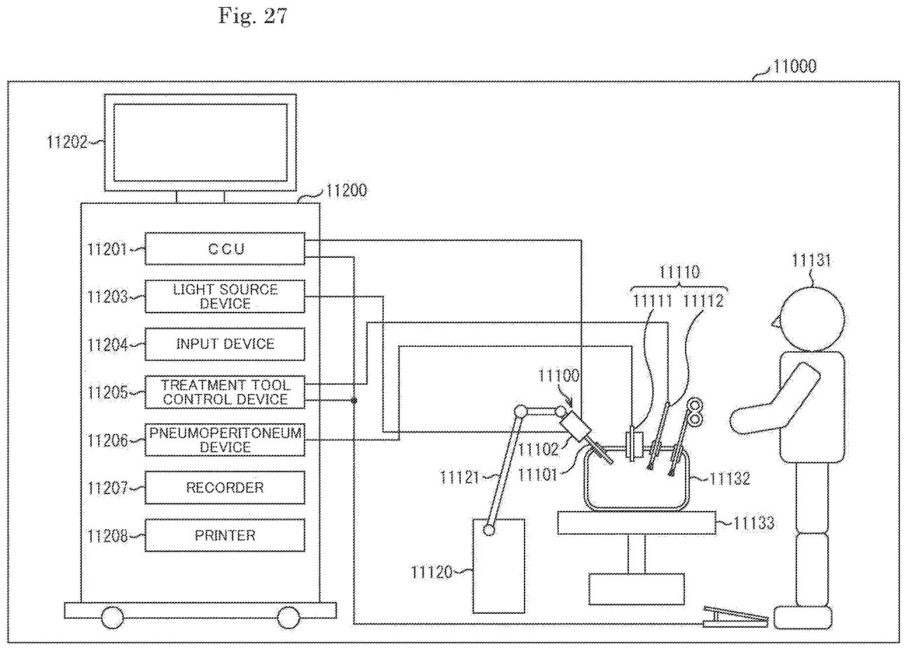

FIG. 27 is a diagram illustrating one example of a schematic configuration of an endoscopic surgery system to which the semiconductor device according to one embodiment of the present technique is applicable.

FIG. 27 illustrates a state in which an operator (doctor) 11131 is performing surgery on a patient 11132 on a patient bed 11133 using the endoscopic surgery system 11000. As illustrated, the endoscopic surgery system 11000 is configured of an endoscope 11100, other surgical instruments 11110 such as a pneumoperitoneum tube 11111 and an energy treatment tool 11112, a support arm device 11120 that supports the endoscope 11100, and a cart 11200 equipped with various devices for endoscopic surgery.

The endoscope 11100 includes a lens barrel 11101 with a region having a predetermined length from a tip thereof to be inserted into the body cavity of the patient 11132, and a camera head 11102 connected to a base end of the lens barrel 11101. In the illustrated example, the endoscope 11100 configured as a so-called rigid endoscope having the rigid lens barrel 11101 is illustrated, but the endoscope 11100 may be configured as a so-called flexible endoscope having a flexible lens barrel.

The distal end of the lens barrel 11101 is provided with an opening into which an objective lens is fitted. A light source device 11203 is connected to the endoscope 11100, light generated by the light source device 11203 is guided to the distal end of the lens barrel 11101 by a light guide extended to the inside of the lens barrel 11101, and the light is radiated toward an observation target in the body cavity of the patient 11132 through the objective lens. The endoscope 11100 may be a direct-viewing endoscope, an oblique-viewing endoscope, or a side-viewing endoscope.

An optical system and an image sensor are provided inside the camera head 11102, and the reflected light (observation light) from the observation target is focused on the image sensor by the optical system. The image sensor photoelectrically converts the observation light, and an electrical signal corresponding to the observation light, that is, an image signal corresponding to an observation image is formed. The image signal is transmitted to a camera control unit (CCU) 11201 as RAW data.

The CCU 11201 is configured of a central processing unit (CPU), a graphics processing unit (GPU), and the like and comprehensively controls the operation of the endoscope 11100 and a display device 11202. In addition, the CCU 11201 receives an image signal from the camera head 11102 and performs various types of image processing for displaying an image based on the image signal, for example, development processing (demosaic processing) on the image signal.

The display device 11202 displays the image based on the image signal subjected to the image processing by the CCU 11201 under the control of the CCU 11201.

The light source device 11203 is configured of, for example, a light source such as an LED (Light Emitting Diode) and supplies the endoscope 11100 with irradiation light when capturing an image of a surgical site or the like.

An input device 11204 is an input interface for the endoscopic surgery system 11000. The user can input various types of information or instructions to the endoscopic surgery system 11000 via the input device 11204. For example, the user inputs an instruction to change image-capturing conditions (a type of applied light, a magnification, a focal length, or the like) of the endoscope 11100 or other instructions.

A treatment tool control device 11205 controls the driving of the energy treatment tool 11112 for cauterization or incision of a tissue, sealing of blood vessels, or the like. A pneumoperitoneum device 11206 sends a gas into the body cavity of the patient 11132 via the pneumoperitoneum tube 11111 in order to inflate the body cavity for the purpose of securing a field of view of the endoscope 11100 and working space of the surgeon. A recorder 11207 is a device capable of recording various types of information on surgery. A printer 11208 is a device capable of printing various types of information on surgery in various formats, such as text, images, and graphs.

The light source device 11203 that supplies applied light for capturing the image of the surgical site to the endoscope 11100 can be configured of, for example, an LED, a laser light source, or a white light source configured of a combination thereof. When a white light source is formed by a combination of RGB laser light sources, it is possible to control the output intensity and the output timing of each color (each wavelength) with high accuracy, and thus the light source device 11203 can adjust the white balance of the captured image. Further, in this case, laser light from each of the respective RGB laser light sources is applied to the observation target in a time division manner, and the driving of the image sensor of the camera head 11102 is controlled in synchronization with the light application timing so that images corresponding to respective RGBs can be captured in a time division manner. According to this method, it is possible to obtain a color image without providing a filter in the image sensor.

Furthermore, the driving of the light source device 11203 may be controlled so that the intensity of output light is changed at predetermined time intervals. The driving of the image sensor of the camera head 11102 is controlled in synchronization with the timing of changing the intensity of the light, and images are acquired in a time division manner and combined, whereby an image having a high dynamic range without so-called blackout and whiteout can be formed.

In addition, the light source device 11203 may have a configuration in which light in a predetermined wavelength band corresponding to special light observation can be supplied. In special light observation, for example, by applying light in a band narrower than that of applied light (that is, white light) during normal observation using wavelength dependence of light absorption in body tissue, so-called narrow band light observation (narrow band imaging) in which images of a predetermined tissue, such as a blood vessel in a mucous film surface layer, is captured with high contrast is performed. Alternatively, in the special light observation, fluorescence observation in which an image is obtained by fluorescence generated by applying excitation light may be performed. The fluorescence observation can be performed by irradiating a body tissue with excitation light and observing fluorescence from the body tissue (autofluorescence observation) or locally injecting a reagent, such as indocyanine green (ICG), to a body tissue and irradiating the body tissue with excitation light corresponding to a fluorescence wavelength of the reagent to obtain a fluorescence image. The light source device 11203 can be configured to be able to supply narrow band light and/or excitation light corresponding to such special light observation.

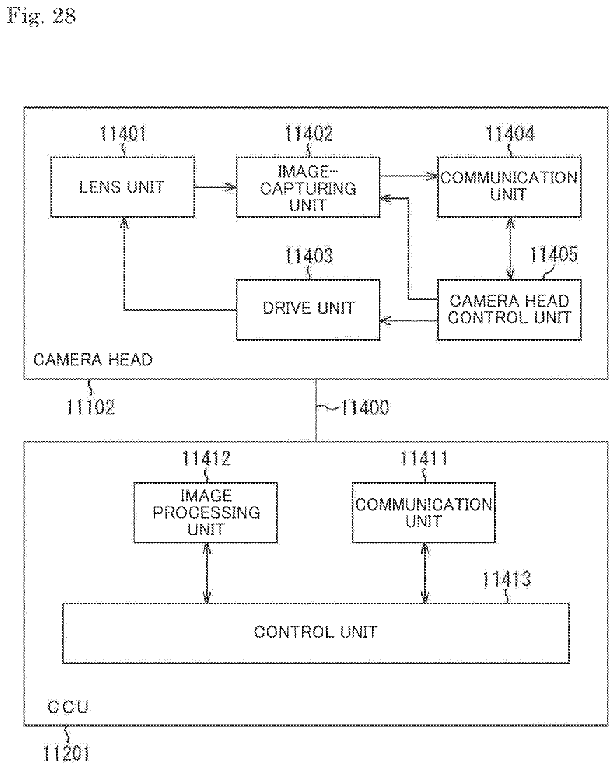

FIG. 28 is a block diagram illustrating one example of a functional configuration of the camera head 11102 and the CCU 11201 illustrated in FIG. 27.

The camera head 11102 includes a lens unit 11401, an image-capturing unit 11402, a drive unit 11403, a communication unit 11404, and a camera head control unit 11405. The CCU 11201 has a communication unit 11411, an image processing unit 11412, and a control unit 11413. The camera head 11102 and the CCU 11201 are communicatively connected to each other by a transmission cable 11400.

The lens unit 11401 is an optical system provided in a connection portion for connection to the lens barrel 11101. Observation light incident on the tip of the lens barrel 11101 is guided to the camera head 11102 and is incident on the lens unit 11401. The lens unit 11401 is configured in combination of a plurality of lenses including a zoom lens and a focus lens.

The image-capturing unit 11402 is configured of an image-capturing device (image sensor). The image sensor constituting the image-capturing unit 11402 may be a single element (a so-called single plate type) or a plurality of elements (a so-called multi-plate type). When the image-capturing unit 11402 may be configured as a multi-plate type, for example, each image sensor may form image signals corresponding to RGB, and a color image may be obtained by synthesizing the image signals. Alternatively, the image-capturing unit 11402 may be configured to include a pair of image sensors for acquiring image signals for the right eye and the left eye adapted to three-dimensional (3D) displaying. Performing 3D displaying allows the surgeon 11131 to more accurately ascertain the depth of a living tissue in the surgical site. When the image-capturing unit 11402 is configured as a multi-plate type, a plurality of systems of lens units 11401 may be provided in correspondence to the image sensors.

The image-capturing unit 11402 need not necessarily be provided in the camera head 11102. For example, the image-capturing unit 11402 may be provided immediately after the objective lens inside the lens barrel 11101.

The drive unit 11403 is configured of an actuator, and the zoom lens and the focus lens of the lens unit 11401 are moved by a predetermined distance along an optical axis under the control of the camera head control unit 11405. Accordingly, the magnification and the focal point of the image captured by the image-capturing unit 11402 can be adjusted appropriately.

The communication unit 11404 is configured of a communication device for transmitting and receiving various types of information to and from the CCU 11201. The communication unit 11404 transmits the image signal obtained from the image-capturing unit 11402 as RAW data to the CCU 11201 via the transmission cable 11400.

The communication unit 11404 receives a control signal for controlling the driving of the camera head 11102 from the CCU 11201 and supplies the control signal to the camera head control unit 11405. For example, the control signal includes information regarding image-capturing conditions, such as information specifying the frame rate of a captured image, information specifying the exposure value at the time of image capturing, and/or information specifying the magnification and the focal point of the captured image.

The image-capturing conditions, such as the frame rate, the exposure value, the magnification, and the focal point, may be appropriately specified by the user, or may be automatically set by the control unit 11413 of the CCU 11201 on the basis of the acquired image signal. In the latter case, the endoscope 11100 should have a so-called auto exposure (AE) function, a so-called auto focus (AF) function, and a so-called auto white balance (AWB) function.

The camera head control unit 11405 controls the driving of the camera head 11102 on the basis of a control signal from the CCU 11201 received via the communication unit 11404.

The communication unit 11411 is configured of a communication apparatus that transmits and receives various kinds of information to and from the camera head 11102. The communication unit 11411 receives an image signal transmitted via the transmission cable 11400 from the camera head 11102.

Furthermore, the communication unit 11411 transmits the control signal for controlling the driving of the camera head 11102 to the camera head 11102. The image signal or the control signal can be transmitted through electric communication, optical communication, or the like.

The image processing unit 11412 performs various types of image processing on the image signal that is the RAW data transmitted from the camera head 11102.

The control unit 11413 performs various kinds of control on capturing an image of a surgical site by the endoscope 11100, display of a captured image obtained through capturing an image of a surgical site, or the like. For example, the control unit 11413 forms a control signal for controlling the driving of the camera head 11102.

In addition, the control unit 11413 causes the display device 11202 to display a captured image showing a surgical site or the like on the basis of an image signal that has been subjected to image processing by the image processing unit 11412. In doing so, the control unit 11413 may recognize various objects in the captured image using various image recognition techniques. For example, the control unit 11413 can recognize a surgical instrument such as forceps, a specific biological site, bleeding, mist at the time of use of the energy treatment tool 11112, or the like by detecting a shape, a color, or the like of an edge of an object included in the captured image. When the display device 11202 is caused to display a captured image, the control unit 11413 may superimpose various kinds of surgery support information on an image of the surgical site and display the superimposed image using a recognition result of the captured image. By displaying the surgery support information in a superimposed manner and presenting it to the surgeon 11131, the burden on the surgeon 11131 can be reduced, and the surgeon 11131 can reliably proceed with the surgery.

The transmission cable 11400 that connects the camera head 11102 and the CCU 11201 is an electrical signal cable compatible with communication of electrical signals, an optical fiber compatible with optical communication, or a composite cable of these.

Here, although wired communication is performed using the transmission cable 11400 in the illustrated example, communication between the camera head 11102 and the CCU 11201 may be performed wirelessly.

One example of an endoscopic surgery system to which the present technique can be applied has been described above. The present technique is applicable to the endoscope 11100, the camera head 11102 (or the image-capturing unit 11402 thereof), and the like out of the configurations described above. Specifically, the semiconductor device according to one embodiment of the present technique can be applied to the image-capturing unit 10402. This can contribute to the sophistication of functions of the endoscope 11100, the camera head 11102 (or the image-capturing unit 11402 thereof), and the like.

While the endoscopic surgery system has been described here as one example, the present technique may be applied to other systems, for example, a microscopic surgery system.

### Application Example 2

### Example of Application to Mobile Body

The present technique can be applied to various products. For example, the semiconductor device according to one embodiment of the present technique may be realized as a device installed in any type of moving body, such as an automobile, an electric vehicle, a hybrid electric vehicle, a motorcycle, a bicycle, a personal mobility device, an airplane, a drone, a ship, and a robot.

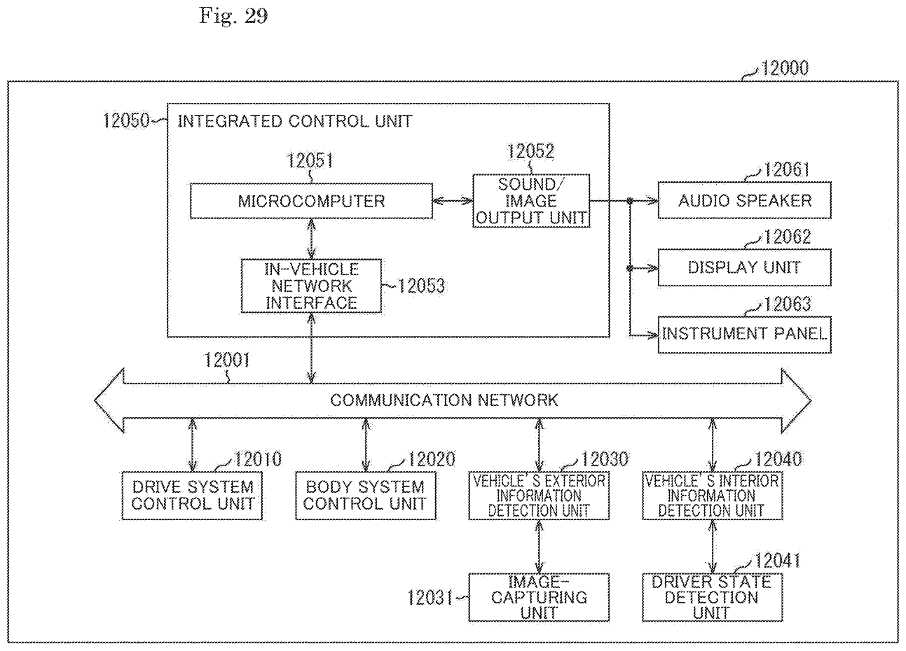

FIG. 29 is a block diagram illustrating a schematic configuration example of a vehicle control system, which is one example of a moving body control system to which the present technique is applicable.

The vehicle control system 12000 includes a plurality of electronic control units connected thereto via a communication network 12001. In the example illustrated in FIG. 29, the vehicle control system 12000 includes a drive system control unit 12010, a body system control unit 12020, a vehicle's exterior information detection unit 12030, a vehicle's interior information detection unit 12040, and an integrated control unit 12050. In addition, as a functional configuration of the integrated control unit 12050, a microcomputer 12051, a sound/image output unit 12052, and an in-vehicle network interface (I/F) 12053 are illustrated.

The drive system control unit 12010 controls the operation of an apparatus related to a drive system of a vehicle according to various programs. For example, the drive system control unit 12010 functions as a driving force generator for generating a driving force of a vehicle such as an internal combustion engine or a driving motor, a driving force transmission mechanism for transmitting a driving force to wheels, a steering mechanism for adjusting a turning angle of a vehicle, and a control apparatus such as a braking apparatus that generates a braking force of a vehicle.

The body system control unit 12020 controls the operations of various devices mounted in the vehicle body according to various programs. For example, the body system control unit 12020 functions as a control device of a keyless entry system, a smart key system, a power window device, or various lamps such as a headlamp, a back lamp, a brake lamp, a turn signal, and a fog lamp. In this case, radio waves transmitted from a portable device that substitutes for a key or signals of various switches may be input to the body system control unit 12020. The body system control unit 12020 receives inputs of the radio waves or signals and controls a door lock device, a power window device, a lamp, and the like of the vehicle.

The vehicle's exterior information detection unit 12030 detects information on the outside of the vehicle having the vehicle control system 12000 mounted thereon. For example, an image-capturing unit 12031 is connected to the vehicle's exterior information detection unit 12030. The vehicle's exterior information detection unit 12030 causes the image-capturing unit 12031 to capture an image of the outside of the vehicle and receives the captured image. The vehicle's exterior information detection unit 12030 may perform object detection processing or distance detection processing for people, cars, obstacles, signs, and letters on the road on the basis of the received image.

The image-capturing unit 12031 is an optical sensor that receives light and outputs an electrical signal according to the amount of the received light. The image-capturing unit 12031 may also output the electrical signal as an image or as distance measurement information. In addition, the light received by the image-capturing unit 12031 may be visible light or invisible light, such as infrared light.

The vehicle's interior information detection unit 12040 detects information on the inside of the vehicle. For example, a driver state detection unit 12041 that detects a driver's state is connected to the vehicle's interior information detection unit 12040. The driver state detection unit 12041 includes, for example, a camera that captures an image of a driver, and the vehicle's interior information detection unit 12040 may calculate the degree of fatigue or concentration of the driver or may determine whether or not the driver is dozing on the basis of detection information inputted from the driver state detection unit 12041.

The microcomputer 12051 may calculate a control target value of the driving force generator, the steering mechanism, or the braking device on the basis of the vehicle's internal or external information acquired by the vehicle's exterior information detection unit 12030 or the vehicle's interior information detection unit 12040, and output a control command to the drive system control unit 12010. For example, the microcomputer 12051 may perform cooperative control for the purpose of implementing functions of an advanced driver assistance system (ADAS) including vehicle collision avoidance, impact mitigation, following traveling based on an inter-vehicle distance, vehicle speed maintenance traveling, vehicle collision warning, or vehicle lane deviation warning.

Furthermore, the microcomputer 12051 can perform cooperative control for the purpose of automated driving, in which automated traveling is performed without the operations by the driver, or the like by controlling the driving force generator, the steering mechanism, or the braking device and the like on the basis of information about the surroundings of the vehicle, the information being acquired by the vehicle's exterior information detection unit 12030 or the vehicle's interior information detection unit 12040.

In addition, the microcomputer 12051 can output a control command to the body system control unit 12020 on the basis of the information acquired by the vehicle's exterior information detection unit 12030 outside the vehicle. For example, the microcomputer 12051 can perform cooperative control for the purpose of preventing glare, such as switching from a high beam to a low beam, by controlling the headlamp according to the position of a preceding vehicle or an oncoming vehicle detected by the vehicle's exterior information detection unit 12030.

The sound/image output unit 12052 sends an output signal of at least one of sound and image to an output device capable of visually or audibly notifying a passenger or the outside of the vehicle of information. In the example of FIG. 29, as output devices, an audio speaker 12061, a display unit 12062, and an instrument panel 12063 are illustrated. The display unit 12062 may include, for example, at least one of an onboard display and a heads-up display.

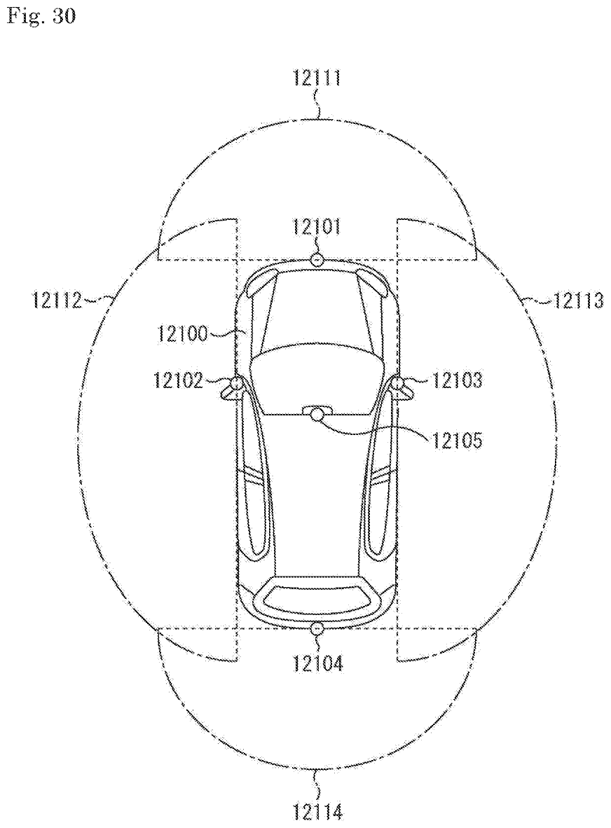

FIG. 30 is a diagram illustrating an example of the installation position of the image-capturing unit 12031.

In FIG. 30, a vehicle 12100 includes image-capturing units 12101, 12102, 12103, 12104, and 12105 as the image-capturing unit 12031.

The image-capturing units 12101, 12102, 12103, 12104, and 12105 are provided at positions such as a front nose, side-view mirrors, a rear bumper, a back door, and an upper portion of a windshield in a vehicle interior of the vehicle 12100, for example. The image-capturing unit 12101 provided on the front nose and the image-capturing unit 12105 provided in the upper portion of the windshield in the vehicle interior mainly acquire images of the front of the vehicle 12100. The image-capturing units 12102 and 12103 provided on the side-view mirrors mainly acquire images of a lateral side of the vehicle 12100. The image-capturing unit 12104 provided on the rear bumper or the back door mainly acquires images of the rear of the vehicle 12100. Front-view images acquired by the image-capturing units 12101 and 12105 are mainly used for detecting preceding vehicles, pedestrians, obstacles, traffic lights, traffic signs, lanes, and the like.

Here, FIG. 30 illustrates one example of image-capturing ranges of the image-capturing units 12101 to 12104. An image-capturing range 12111 indicates an image-capturing range of the image-capturing unit 12101 provided at the front nose, image-capturing ranges 12112 and 12113 respectively indicate the image-capturing ranges of the image-capturing units 12102 and 12103 provided at the side-view mirrors, and an image-capturing range 12114 indicates the image-capturing range of the image-capturing unit 12104 provided at the rear bumper or the back door. For example, by superimposing image data captured by the image-capturing units 12101 to 12104, it is possible to obtain a bird's-eye view image viewed from the upper side of the vehicle 12100.

At least one of the image-capturing units 12101 to 12104 may have a function for obtaining distance information. For example, at least one of the image-capturing units 12101 to 12104 may be a stereo camera configured of a plurality of image sensors or may be an image sensor that has pixels for phase difference detection.

For example, the microcomputer 12051 can extract, particularly, the closest three-dimensional object on a path along which the vehicle 12100 is traveling, which is a three-dimensional object traveling at a predetermined speed (for example, 0 km/h or higher) in the substantially same direction as the vehicle 12100, as a vehicle ahead by acquiring a distance to each three-dimensional object in the image-capturing ranges 12111 to 12114 and a temporal change of this distance (a relative speed with respect to the vehicle 12100) on the basis of the distance information obtained from the image-capturing units 12101 to 12104. Furthermore, the microcomputer 12051 can set an inter-vehicle distance to be secured from a vehicle ahead in advance with respect to the vehicle ahead and can perform automated brake control (also including following stop control) or automated acceleration control (also including following start control). In this way, cooperative control can be performed for the purpose of automated traveling or the like in which a vehicle automatedly travels without the operations of the driver.

For example, the microcomputer 12051 can classify and extract three-dimensional data regarding three-dimensional objects into two-wheeled vehicles, normal vehicles, large vehicles, pedestrians, and other three-dimensional objects, such as electric poles, on the basis of the distance information obtained from the image-capturing units 12101 to 12104 and can use the three-dimensional data to perform automated avoidance of obstacles. For example, the microcomputer 12051 differentiates the surrounding obstacles of the vehicle 12100 into obstacles that can be viewed by the driver of the vehicle 12100 and obstacles that are difficult to view. Then, the microcomputer 12051 determines a collision risk indicating the degree of risk of collision with each obstacle, and when the collision risk is equal to or higher than a set value and there is a possibility of collision, the microcomputer 12051 can output an alarm to the driver through the audio speaker 12061 or the display unit 12062, can perform forced deceleration or avoidance steering through the drive system control unit 12010, thereby performing driving support for collision avoidance.

At least one of the image-capturing units 12101 to 12104 may be an infrared camera that detects infrared rays. For example, the microcomputer 12051 may recognize a pedestrian by determining whether there is a pedestrian in the image captured by the image-capturing units 12101 to 12104. For example, such pedestrian recognition is performed by a procedure in which feature points in the captured images of the image-capturing units 12101 to 12104 as infrared cameras are extracted and a procedure in which pattern-matching processing is performed on a series of feature points indicating an outline of an object to determine whether or not the object is a pedestrian. When the microcomputer 12051 determines that there is a pedestrian in the captured images of the image-capturing units 12101 to 12104 and the pedestrian is recognized, the sound/image output unit 12052 controls the display unit 12062 so that a square contour line for emphasis is superimposed and displayed with the recognized pedestrian. In addition, the sound/image output unit 12052 may control the display unit 12062 so that an icon indicating a pedestrian or the like is displayed at a desired position.

One example of the vehicle control system to which the present technique is applicable has been described above. The semiconductor device according to one embodiment of the present technique is applicable to the image-capturing unit 12031 or the like out of the configurations described above. Specifically, the semiconductor device according to one embodiment of the present technique can be applied to the image-capturing unit 12031. Application of the present technique to the image-capturing unit 12031 contributes to the sophistication of functions.

The above description of the electronic device according to the seventh embodiment of the present technique can be applied to other embodiments of the present technique as long as there is no particular technical contradiction.

### 11. Eighth Embodiment of Present Technique (Example 1 of Method for Producing Semiconductor Device)

The method for producing a semiconductor device according to one embodiment of the present technique is a method for producing a semiconductor device, including: joining a first semiconductor element and each of a plurality of second semiconductor elements with a circuit configured to process the signals from the first semiconductor element; forming first films on each of the plurality of second semiconductor element; and patterning the first films so that the first films remain on at least one of the plurality of second semiconductor elements.

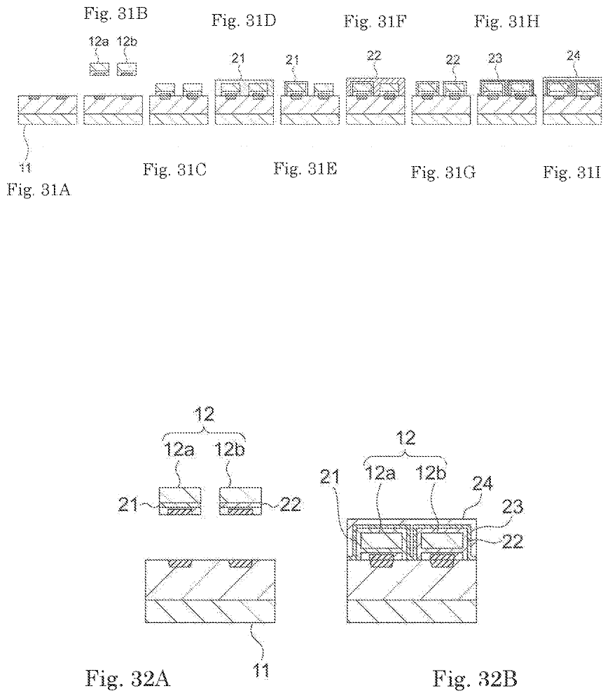

A method for producing a semiconductor device according to one embodiment of the present technique will be described with reference to FIG. 31. FIG. 31 is a diagram illustrating an example of a production process of a semiconductor device according to one embodiment of the present technique.

First, as illustrated in FIG. 31A, an oxide film bonding layer 3 is formed on the first semiconductor element 11.

Next, as illustrated in FIGS. 31B and 31C, a first semiconductor element 11 and each of a plurality of second semiconductor elements 12 are electrically connected by, for example, Cu—Cu bonding or the like.

Next, as illustrated in FIG. 31D, a first film 21 is formed on each of a plurality of second semiconductor elements 12.

Next, as illustrated in FIG. 31E, the first film 21 is patterned so that the first film 21 remains only on the second semiconductor element 12.

Next, as illustrated in FIG. 31F, a second film 22 is formed on each of the plurality of second semiconductor elements 12.

Next, as illustrated in FIG. 31G, patterning processing is performed so that the second film 22 remains only on the second semiconductor element 12.

Next, as illustrated in FIG. 31H, a third film 23 is formed on each of the plurality of second semiconductor elements 12.

Finally, as illustrated in FIG. 31I, a fourth film 24 is formed as an embedding member on each of the plurality of second semiconductor elements 12.

The above description of the method for producing a light-receiving element according to the eighth embodiment of the present technique can be applied to other embodiments of the present technique as long as there is no particular technical contradiction.

### 12. Ninth Embodiment of Present Technique (Example 2 of Method for Producing Semiconductor Device)

A method for producing a semiconductor device in which a film is formed on the entire surface of a second semiconductor element, as illustrated in FIG. 14, will be described with reference to FIG. 32. FIG. 32 is a diagram illustrating an example of a production process of a semiconductor device according to one embodiment of the present technique.

First, as illustrated in FIG. 32A, a first film 21 is formed below the second semiconductor element 12, and an oxide film bonding layer 3 is formed below the first film 21. A second film 22 is formed below the second semiconductor element 12, and the oxide film bonding layer 3 is formed below the second film 22.

After that, when the production is performed by the procedure illustrated in FIG. 31, a semiconductor device 100 in which a film is formed on the entire surface of a second semiconductor element 12 is produced, as illustrated in FIG. 32B.

The above description of the method for producing a light-receiving element according to the ninth embodiment of the present technique can be applied to other embodiments of the present technique as long as there is no particular technical contradiction.

### 13. Tenth Embodiment of Present Technique (Example 3 of Method for Producing Semiconductor Device)

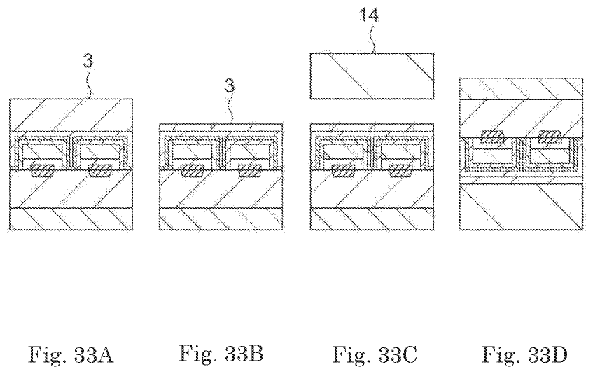

A method for producing a semiconductor device provided with a support substrate, as illustrated in FIG. 15, will be described with reference to FIG. 33. FIG. 33 is a diagram illustrating an example of a production process of a semiconductor device according to one embodiment of the present technique.

First, as illustrated in FIG. 33A, an oxide film bonding layer 3 is formed on the semiconductor device produced in the procedure illustrated in FIG. 31.

Next, as illustrated in FIG. 33B, the surface of the oxide film bonding layer 3 is flattened by CMP.

Next, as illustrated in FIG. 33C, a support substrate 14 is bonded by oxide film bonding.

Finally, as illustrated in FIG. 33D, the semiconductor device is inverted so that the top surface becomes the bottom surface.

The above description of the method for producing a light-receiving element according to the tenth embodiment of the present technique can be applied to other embodiments of the present technique as long as there is no particular technical contradiction.

Note that the embodiment of the present technique is not limited to the embodiments mentioned above, and various modifications can be made without departing from the gist of the present technique.

The present technique can be configured as follows.

[1]

A semiconductor apparatus including:
a first semiconductor element; and
a plurality of second semiconductor elements with a circuit configured to process a signal from the first semiconductor element,
the first semiconductor element and each of the plurality of second semiconductor elements being stacked and arranged; and
a first film formed on at least one of the plurality of second semiconductor elements being different in configuration from a second film formed on another of the second semiconductor elements.
   [2]

The semiconductor device according to [1], wherein the first film is different in type from the second film.

[3]

The semiconductor device according to [1] or [2], wherein the first film is different in thickness from the second film.

[4]

The semiconductor device according to any one of [1] to [3], wherein the first film is different in number from the second film.

[5]

The semiconductor device according to any one of [1] to [4], wherein the first film has a stress-regulating function.

[6]

The semiconductor device according to [5], wherein the first film has a compressive stress-regulating function and contains at least one selected from the group consisting of SiN, SiO2, TiN, TaN, and SiGe epitaxial layers.

[7]

The semiconductor device according to [5], wherein the first film has a tensile stress-regulating function and contains at least one selected from the group consisting of SiN and AlO.

[8]

The semiconductor device according to any one of [5] to [7], wherein the first film contains a high melting point metal material.

[9]

The semiconductor device according to [8], wherein the first film contains at least one selected from the group consisting of SiON, AlN, Si, Ge, Mo, W, Ti, Ta, MoSi, WSi, and TiSi.

[10]

The semiconductor device according to any one of [1] to [9], wherein the first film has an oxygen-regulating function.

[11]

The semiconductor device according to [10], wherein
the first film has an oxygen-absorbing function and contains at least one selected from the group consisting of polysilicon, amorphous silicon, and SiGe.
   [12]

The semiconductor device according to [10], wherein
the first film has an oxygen supply function and contains at least one selected from the group consisting of aluminum, silicon, and hafnium and also contains at least one selected from the group consisting of an oxide film, a nitride film, and an oxynitride film.
   [13]

The semiconductor device according to [10], wherein
the first film has an oxygen diffusion prevention function and contains at least one selected from the group consisting of boron, carbon, nitrogen, oxygen, fluorine, magnesium, aluminum, silicon, phosphorus, chlorine, argon, gallium, germanium, yttrium, zirconium, lanthanum, neodymium, hafnium, bismuth, niobium, tungsten, titanium, molybdenum, copper, ruthenium, nickel, or tantalum and also contain at least one selected from the group consisting of an oxide film, a nitride film, an oxynitride film, a metal, and an alloy.
   [14]

The semiconductor device according to any one of [1] to [13], wherein the first film has a hydrogen-regulating function.

[15]

The semiconductor device according to [14], wherein
the first film has a hydrogen-absorbing function and contains at least one selected from the group consisting of Ti, Zr, Pd, V, Ta, Fe, Co, Ni, Cr, Pt, Cu, Ag, La, Th, Y, Nb, Hf, Sc, Lu, Ru, Rh, Ir, Os, and Mg.
   [16]

The semiconductor device according to [14], wherein
the first film has a hydrogen supply function and contains at least one selected from the group consisting of silicon nitride, silicon oxide, oxidized silicon carbide, HSQ, an organic film, TEOS, BPSG, BSG, PSG, FSG, carbon-containing silicon nitride, and amorphous silicon.
   [17]

The semiconductor device according to [14], wherein
the first film has a hydrogen diffusion prevention function and contains at least one selected from the group consisting of silicon nitride, silicon oxynitride, low dielectric constant carbon-containing silicon oxide, silicon carbide, aluminum oxide, aluminum, tungsten, erbium oxide, TiAl alloy, a nitride of TiAl alloy, amorphous silicon, and SiC.

The semiconductor device according to any one of [1] to [17], wherein a plurality of the first semiconductor elements are stacked and arranged.

[19]

The semiconductor device according to any one of [1] to [18], wherein the first semiconductor element, each of the plurality of second semiconductor elements, and the first semiconductor element are stacked and arranged in this order.

[20]

The semiconductor device according to any one of [1] to [19], further including: a plurality of third semiconductor elements with a circuit configured to process a signal from the first semiconductor element, wherein each of the plurality of second semiconductor elements, the first semiconductor element, and each of the plurality of third semiconductor elements are stacked and arranged in this order.

[21]

The semiconductor device according to any one of [1] to [20], wherein the first semiconductor element, each of the plurality of second semiconductor elements, and each of the third semiconductor elements are stacked and arranged in this order.

[22]

The semiconductor device according to any one of [1] to [21], wherein each of the plurality of second semiconductor elements is different in orientation in plan view from each of the plurality of third semiconductor elements.

[23]

The semiconductor device according to any one of [1] to [22], further including a support substrate.

An electronic device including the semiconductor device according to any one of [1] to [23].

[25]

A method for manufacturing a semiconductor device, including:
joining a first semiconductor element and each of a plurality of second semiconductor elements with a circuit configured to process a signal from the first semiconductor element;
forming first films on each of the plurality of second semiconductor elements; and
patterning the first films so that the first films remain on at least one of the plurality of second semiconductor elements.

### REFERENCE SIGNS LIST

100 Semiconductor device
11 First semiconductor element
12 Second semiconductor element
13 Third semiconductor element
14 Support substrate
21 First film
22 Second film
23 Third film
24 Fourth film

What is claimed is:

1. A semiconductor device, comprising:
a first semiconductor element; and
a plurality of second semiconductor elements with a circuit configured to process a signal from the first semiconductor element,
the first semiconductor element and each of the plurality of second semiconductor elements being stacked and arranged; and
a first film formed on at least one of the plurality of second semiconductor elements being different in configuration from a second film formed on another of the second semiconductor elements.

2. The semiconductor device according to claim 1, wherein
the first film is different in type from the second film.

3. The semiconductor device according to claim 1, wherein
the first film is different in thickness from the second film.

4. The semiconductor device according to claim 1, wherein
the first film is different in number from the second film.

5. The semiconductor device according to claim 1, wherein
the first film has a stress-regulating function.

6. The semiconductor device according to claim 5, wherein
the first film has a compressive stress-regulating function and contains at least one selected from the group consisting of SiN, SiO2, TiN, TaN, and SiGe epitaxial layers.

7. The semiconductor device according to claim 5, wherein
the first film has a tensile stress-regulating function and contains at least one selected from the group consisting of SiN and AlO.

8. The semiconductor device according to claim 5, wherein
the first film contains a high melting point metal material.

9. The semiconductor device according to claim 8, wherein
the first film contains at least one selected from the group consisting of SiON, AlN, Si, Ge, Mo, W, Ti, Ta, MoSi, WSi, and TiSi.

10. The semiconductor device according to claim 1, wherein
the first film has an oxygen-regulating function.

11. The semiconductor device according to claim 10, wherein
the first film has an oxygen-absorbing function and contains at least one selected from the group consisting of polysilicon, amorphous silicon, and SiGe.

12. The semiconductor device according to claim 10, wherein
the first film has an oxygen supply function and contains at least one selected from the group consisting of aluminum, silicon, and hafnium and also contains at least one selected from the group consisting of an oxide film, a nitride film, and an oxynitride film.

13. The semiconductor device according to claim 10, wherein
the first film has an oxygen diffusion prevention function and contains at least one selected from the group consisting of boron, carbon, nitrogen, oxygen, fluorine, magnesium, aluminum, silicon, phosphorus, chlorine, argon, gallium, germanium, yttrium, zirconium, lanthanum, neodymium, hafnium, bismuth, niobium, tungsten, titanium, molybdenum, copper, ruthenium, nickel, or tantalum and also contain at least one selected from the group consisting of an oxide film, a nitride film, an oxynitride film, a metal, and an alloy.

14. The semiconductor device according to claim 1, wherein
the first film has a hydrogen-regulating function.

15. The semiconductor device according to claim 14, wherein
the first film has a hydrogen-absorbing function and contains at least one selected from the group consisting of Ti, Zr, Pd, V, Ta, Fe, Co, Ni, Cr, Pt, Cu, Ag, La, Th, Y, Nb, Hf, Sc, Lu, Ru, Rh, Ir, Os, and Mg.

16. The semiconductor device according to claim 14, wherein
the first film has a hydrogen supply function and contains at least one selected from the group consisting of silicon nitride, silicon oxide, oxidized silicon carbide, HSQ, an organic film, TEOS, BPSG, BSG, PSG, FSG, carbon-containing silicon nitride, and amorphous silicon.

17. The semiconductor device according to claim 14, wherein
the first film has a hydrogen diffusion prevention function and contains at least one selected from the group consisting of silicon nitride, silicon oxynitride, low dielectric constant carbon-containing silicon oxide, silicon carbide, aluminum oxide, aluminum, tungsten, erbium oxide, a TiAl alloy, a nitride of a TiAl alloy, amorphous silicon, and SiC.

18. The semiconductor device according to claim 1, wherein
a plurality of the first semiconductor elements are stacked and arranged.

19. The semiconductor device according to claim 1, wherein
the first semiconductor element, each of the plurality of second semiconductor elements, and the first semiconductor element are stacked and arranged in this order.

20. The semiconductor device according to claim 1, further comprising:
a plurality of third semiconductor elements with a circuit configured to process a signal from the first semiconductor element, wherein
each of the plurality of second semiconductor elements, the first semiconductor element, and each of the plurality of third semiconductor elements are stacked and arranged in this order.

21. The semiconductor device according to claim 1, wherein
the first semiconductor element, each of the plurality of second semiconductor elements, and each of the third semiconductor elements are stacked and arranged in this order.

22. The semiconductor device according to claim 1, wherein
each of the plurality of second semiconductor elements is different in orientation in plan view from each of the plurality of third semiconductor elements.

23. The semiconductor device according to claim 1, further comprising
a support substrate.

24. An electronic device comprising the semiconductor device according to claim 1.

25. A method for manufacturing a semiconductor device, comprising:
joining a first semiconductor element and each of a plurality of second semiconductor elements with a circuit configured to process a signal from the first semiconductor element;
forming first films on each of the plurality of second semiconductor elements; and
patterning the first films so that the first films should remain on at least one of the plurality of second semiconductor elements.
